(19) United States
(12) Patent Application Publication
(10) Pub. No.: US 2026/0359531 A1
(43) Pub. Date: Nov. 12, 2026

(54) RESERVOIR MODELING

(71) Applicant: BP Exploration Operating Company Limited, Middlesex (GB)

(72) Inventors: Emma Louise Nesbit, Windsor (GB); Matthew James McQueen, Keinton Mandeville (GB); Obiajulu Joseph Isebor, Fulshear, TX (US); Andy Julian Beer, Chagford (GB); Robert James King, Haslemere (GB); Mark Mansfield, Staines-upon-Thames (GB)

(73) Assignee: BP Exploration Operating Company Limited, Middlesex (GB)

(21) Appl. No.: 19/669,930

(22) Filed: May 6, 2026

Related U.S. Application Data
(60) Provisional application No. 63/803,200, filed on May 9, 2025.

(51) Int. Cl. G06F 30/28

(52) U.S. Cl. CPC G06F 30/28

(57) ABSTRACT

Methods, systems, and apparatus, including computer programs encoded on a computer storage medium, for modeling a reservoir are disclosed. In one aspect, a method includes the actions of accessing a model of a subsurface reservoir. The actions include segmenting the model into equal-sized cells. The actions include determining geological characteristics of each of the equal-sized cells. The actions include determining a transmissibility between pairs of the equal-sized cells. The actions include providing data based on (i) the geological characteristics of each of the equal-sized cells, (ii) the transmissibility between the pairs of the equal-sized cells, and (iii) a future point in time to a simulator that is configured to determine given geological characteristics of a given subsurface reservoir at a given future point in time. The actions include receiving, from the simulator, data indicating additional geological characteristics of the subsurface reservoir at the future point in time.

### CROSS-REFERENCE TO RELATED APPLICATION

This application claims the benefit of US Provisional Application 63/803,200 filed May 9, 2025, and entitled “Reservoir Modeling,” which is hereby incorporated herein by reference in its entirety.

### STATEMENT REGARDING FEDERALLY SPONSORED RESEARCH OR DEVELOPMENT

Not applicable.

### BACKGROUND

Reservoir modeling involves the construction of a computer model of a subsurface reservoir (fossil fuel, CO2, etc.), for the purposes of improving estimation of reserves and making decisions regarding the development of the field, predicting future production and/or injection, placing additional wells and evaluating alternative reservoir management scenarios.

### SUMMARY

An innovative aspect of the subject matter described in this specification may be implemented in a method for modeling reservoirs using regular and abstract grids. The method includes the action of accessing or generating a model of a subsurface reservoir. The method further includes the action of segmenting the model of the subsurface reservoir into equal-sized cells. The method further includes the action of determining geological characteristics of each of the equal-sized cells. The method further includes the action of determining a transmissibility between pairs of the equal-sized cells. The method further includes the action of providing data based on (i) the geological characteristics of each of the equal-sized cells, (ii) the transmissibility between the pairs of the equal-sized cell, and (iii) a future point in time to a simulator that is configured to determine given geological characteristics of a given subsurface reservoir at a given future point in time. The method further includes the action of receiving, from the simulator, data indicating additional geological characteristics of the subsurface reservoir at the future point in time.

Other implementations of this aspect include corresponding systems, apparatus, and computer programs recorded on computer storage devices, each configured to perform the operations of the method.

Another innovative aspect of the subject matter described in this specification may be implemented in a method for using a regular grid in reservoir modeling. The method includes the action of accessing or generating a model of a subsurface reservoir that includes data identifying geological features of the subsurface reservoir. The method further includes the action of segmenting the model of the subsurface reservoir into equal-sized cells. The method further includes the action of comparing each of the equal-sized cells to a geological feature of the geological features of the subsurface reservoir. Based on comparing each of the equal-sized cells to the geological feature of the geological features of the subsurface reservoir, the method further includes the action of assigning each of the equal-sized cells to a first side of the geological feature or to a second side of the geological feature.

Other implementations of this aspect include corresponding systems, apparatus, and computer programs recorded on computer storage devices, each configured to perform the operations of the method.

Another innovative aspect of the subject matter described in this specification may be implemented in a method for generating abstract dynamic grids. The method includes the action of accessing or generating a model of a subsurface reservoir that is segmented into equal-sized cells. The method further includes the action of generating cell groups that each comprise a group of neighboring equal-sized cells of the equal-sized cells. The method further includes the action of determining geological characteristics of each of the cell groups. The method further includes the action of determining a transmissibility between pairs of the cell groups. The method further includes the action of generating a network that comprises nodes that represent each of the cell groups and edges that represent connections between the pairs of the cell groups, wherein each node includes the geological characteristics of a corresponding cell group and each edge includes the transmissibility between corresponding pairs of the cell groups.

Other implementations of this aspect include corresponding systems, apparatus, and computer programs recorded on computer storage devices, each configured to perform the operations of the method.

Another innovative aspect of the subject matter described in this specification may be implemented in a method for upscaling tensor permeability when transitioning from regular to abstract grids. The method includes the action of generating or accessing a model of a subsurface reservoir that is segmented into cell groups that each comprise equal-sized cells of the subsurface reservoir. The method further includes the action of selecting a cell group of the cell groups. The method further includes the action of determining a cuboid that includes the equal-sized cells of the cell group and extra equal-sized cells of the equal-sized cells. The method further includes the action of determining a cell permeability of each of the equal-sized cells of the cell group and the extra equal-sized cells. Based on the cell permeability of each of the equal-sized cells of the cell group and the extra equal-sized cells, the method further includes the action of determining a group permeability of the cell group.

Other implementations of this aspect include corresponding systems, apparatus, and computer programs recorded on computer storage devices, each configured to perform the operations of the method.

Embodiments described herein comprise a combination of features and characteristics intended to address various shortcomings associated with certain prior devices, systems, and methods. The foregoing has outlined rather broadly the features and technical characteristics of the disclosed embodiments in order that the detailed description that follows may be better understood. The various characteristics and features described above, as well as others, will be readily apparent to those skilled in the art upon reading the following detailed description, and by referring to the accompanying drawings. It should be appreciated that the conception and the specific embodiments disclosed may be readily utilized as a basis for modifying or designing other structures for carrying out the same purposes as the disclosed embodiments. It should also be realized that such equivalent constructions do not depart from the spirit and scope of the principles disclosed herein.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1 illustrates an example inputs to a model of a subsurface reservoir in accordance with principles described herein.

FIG. 2 illustrates an example grid of a two-dimensional representation of a subsurface reservoir in accordance with principles described herein.

FIG. 3 illustrates an example grid divided into strata in accordance with principles described herein.

FIG. 4 illustrates an example grid divided into segments in accordance with principles described herein.

FIG. 5 illustrates an example grid divided into model structural units (MSUs) in accordance with principles described herein.

FIG. 6 illustrates an example grid divided into MSUs that is prepared for reservoir simulation in accordance with principles described herein.

FIG. 7 illustrates an example transition from a regular grid to an abstract representation of the grid in accordance with principles described herein.

FIG. 8 illustrates an example transition from a regular grid to an abstract representation of the grid in accordance with principles described herein.

FIG. 9 illustrates an example interaction between a simulator and networks representing cell groups in accordance with principles described herein.

FIG. 10 illustrates an example workflow for accelerated reservoir modelling using regular and abstract grids with gridding stage in accordance with principles described herein.

FIG. 11 illustrates a comparison of irregular grid (corner point), block grid, and regular grid in accordance with principles described herein.

FIG. 12 illustrates an example scene with frontier polygon, curtain, and ceiling and floor planar surfaces in accordance with principles described herein.

FIG. 13 illustrates an example regular grid superimposed over the container space, with a frontier polygon in accordance with principles described herein.

FIG. 14 illustrates an example container with the frontier curtain gridded onto cell faces in accordance with principles described herein.

FIG. 15 illustrates an example section of grid with a straight line between cell centers shown intersecting a triangle in a surface in accordance with principles described herein.

FIG. 16A illustrates an example projection of a triangle in the plan view in accordance with principles described herein.

FIG. 16B illustrates an example triangle with regular grid overlaid in accordance with principles described herein.

FIG. 17 illustrates an example triangular surface together with a grid frontier curtain and an example triangular surface with the gridded cell faces overlaid together with a grid frontier curtain in accordance with principles described herein.

FIG. 18 illustrates example cells divided by strata, segments, and model structural units in accordance with principles described herein.

FIG. 19 illustrates an example triangular surface with the gridded cell faces overlaid together with a grid frontier curtain and an example extended surface with the corresponding gridded cell faces reaching the edge of the regular grid with a grid frontier curtain in accordance with principles described herein.

FIG. 20 illustrates an example grid frontier curtain with cells allocated to true and the original surface in accordance with principles described herein.

FIG. 21 illustrates an example segment allocation at a coarse rank and an example segment allocation at a fine rank in accordance with principles described herein.

FIG. 22 illustrates an example multi-rank stratigraphic column in accordance with principles described herein.

FIG. 23 illustrates an example strata allocation at various ranks in accordance with principles described herein.

FIG. 24 illustrates example sub-strata with a thinning stratum in accordance with principles described herein.

FIG. 25 illustrates example proportional sub-strata, after allocation to columns of cells, with a variation in the parent stratum thickness in accordance with principles described herein.

FIG. 26 illustrates an example dipping stratum and a relationship between true stratigraphic thickness and true vertical thickness in accordance with principles described herein.

FIG. 27 illustrates example sub-strata that are proportional and extrapolated from a full column across to a fault in accordance with principles described herein.

FIG. 28 illustrates an example geobody in accordance with principles described herein.

FIG. 29 illustrates an example schematic showing the downwards shadow from a top geobody surface, the upwards shadow from a base geobody surface, and the intersection of shadows that is the volume allocated to the geobody in accordance with principles described herein.

FIG. 30 illustrates an example grid showing large geobodies cutting into a background stratum, with some minor geobodies within major geobodies in accordance with principles described herein.

FIG. 31 illustrates example grids of a subsurface area in accordance with principles described herein.

FIG. 32 illustrates an example model building process using a coarse-fine-coarse setup in accordance with principles described herein.

FIG. 33 illustrates an example abstract dynamic model process that generates different resolutions of a model by allocating cells accordingly to yield abstract models in accordance with principles described herein.

FIG. 34 illustrates an example grid where the cells have varying importance values in accordance with principles described herein.

FIG. 35 illustrates an example two-dimensional regular grid with a set of cells comprising a single coarse abstract cell in accordance with principles described herein.

FIG. 36 illustrates an example fine grid and a coarse grid in accordance with principles described herein.

FIG. 37 illustrates an example two-dimensional coarse abstract cell built from an aggregation of two dimensional fine scale regular grid cells in accordance with principles described herein.

FIG. 38 illustrates an example cell and bedding plane in accordance with principles described herein.

FIG. 39 illustrates an example cuboid upscaling computational box in two dimensions for a single coarse abstract cell in accordance with principles described herein.

FIG. 40 is a flowchart of an example process for modeling a reservoir using regular and abstract grids in accordance with principles described herein.

FIG. 41 is a flowchart of an example process for using a regular grid to model a reservoir in accordance with principles described herein.

FIG. 42 is a flowchart of an example process for generating an abstract dynamic grid in accordance with principles described herein.

FIG. 43 is a flowchart of an example process for upscaling tensor permeability from regular to abstract grids in accordance with principles described herein.

### DETAILED DESCRIPTION

The following discussion is directed to various exemplary embodiments. However, one skilled in the art will understand that the examples disclosed herein have broad application, and that the discussion of any embodiment is meant only to be exemplary of that embodiment, and not intended to suggest that the scope of the disclosure, including the claims, is limited to that embodiment.

Certain terms are used throughout the following description and claims to refer to particular features or components. As one skilled in the art will appreciate, different persons may refer to the same feature or component by different names. This document does not intend to distinguish between components or features that differ in name but not function. The drawing figures are not necessarily to scale. Certain features and components herein may be shown exaggerated in scale or in somewhat schematic form and some details of conventional elements may not be shown in interest of clarity and conciseness.

Unless the context dictates the contrary, all ranges set forth herein should be interpreted as being inclusive of their endpoints, and open-ended ranges should be interpreted to include only commercially practical values. Similarly, all lists of values should be considered as inclusive of intermediate values unless the context indicates the contrary. Where numerical ranges or limitations are expressly stated, such express ranges or limitations should be understood to include iterative ranges or limitations of like magnitude falling within the expressly stated ranges or limitations (e.g., from about 1 to about 10 includes, 2, 3, 4, etc.; greater than 0.10 includes 0.11, 0.12, 0.13, etc.).

In the following discussion and in the claims, the terms “including” and “comprising” are used in an open-ended fashion, and thus should be interpreted to mean “including, but not limited to… .” Use of the term "optionally" with respect to any element of a claim is intended to mean that the subject element is required, or alternatively, is not required. Both alternatives are intended to be within the scope of the claim. The term “couple” or “couples” is intended to mean either an indirect or direct connection. As used herein, the terms “approximately,” “about,” “substantially,” and the like mean within 10% (i.e., plus or minus 10%) of the recited value. Thus, for example, a recited angle of “about 80 degrees” refers to an angle ranging from 72 degrees to 88 degrees.

### Overview

The modeling methods described below build reservoir simulation models by relying on advanced computing capabilities, when compared with other example modelling methods. This approach reduces the time taken to build models, by providing a chained workflow spanning multiple disciplines, from seismic interpretations through to simulation outputs. Models, and ensembles of models can be built quickly and rerun by multiple disciplines. This allows for fast integration of new data, better testing of uncertainties, and rapid generation of different models to answer specific questions and support reservoir management decisions.

The modeling methods and workflows described below have several features. First, the workflows are chained together using interpreted languages and markup languages. The workflows use a common data standard that avoids the need for file handovers and manual file editing. Second, the methods utilize high performance computing by leveraging both massive-scale parallelism and large memory pools. This helps to improve speed and replaces manual model building steps. Third, the methods use regular grids with automated rasterization of interpretation. This technique helps to avoid manual corner-point grid building and allows multiple structural interpretations. Fourth, the methods use abstract, unstructured grids for simulation. This technique allows models to be simulated at a range of resolutions. Fifth, the methods use full-tensor permeability upscaling techniques.

The methods and workflows use high performance computing for model building and various unique techniques in modeling. This results in workflows with the potential for reduced cycle times compared to alternative approaches. A first technique involves models being built using regular grids, with orthogonal axes and constant DXYZ dimensions in each cell. This approach allows the building of models with multiple alternate structural interpretations and the generating of models at any resolution.

A second technique involves the models being automatically upscaled and converted from fine-scale into abstract grids ahead of simulation, with cell depths, pore volumes and transmissibilities being calculated and inputted into a simulator as an unstructured or structured grid. This approach allows the running of models at a variety of resolutions, for example, from a material balance scale through to a fine scale.

A third technique involves upscaling permeabilities and calculating transmissibilities in the abstract grids. This approach handles the misalignment of flow directions between regular grids and the geological bedding planes.

An example modeling workflow may be manual and time-intensive, with cycle times from several months to years and sometimes involving multiple discipline handovers. With the manual and time-consuming nature of these workflows, a modeling system may be locked into early modelling decisions, as the resources required to make changes and propagate these through the workflow is prohibitive. Timely incorporation of new data may be restricted. In some cases, it may not be possible to update models, and, instead, they must be rebuilt. This may be true where changes to the input seismic interpretation or structure are needed; changes that require a new grid may lead to a full model rebuild. For this reason, example modeling systems may not consider multiple interpretations or explore the full impact of structural uncertainty using the models.

The long cycle time of some example modelling approaches leads to models often being used to answer questions for which they were not built, as it can be challenging to repurpose a model with new data, or to focus on specific sectors or areas of interest. In some implementations, reservoir modelling allows integrating data from multiple disciplines, testing the impact of uncertainty on field performance, and informing reservoir management decisions. The ability to integrate new data, from multiple disciplines and in a timely manner, and to investigate the impact of uncertainties is key in generating models which have predictive power, and can influence decisions.

In summary, the workflow described in this specification, which can fully explore structural uncertainty, will help to unlock reservoir modelling as an appropriate tool to support subsequent decisions.

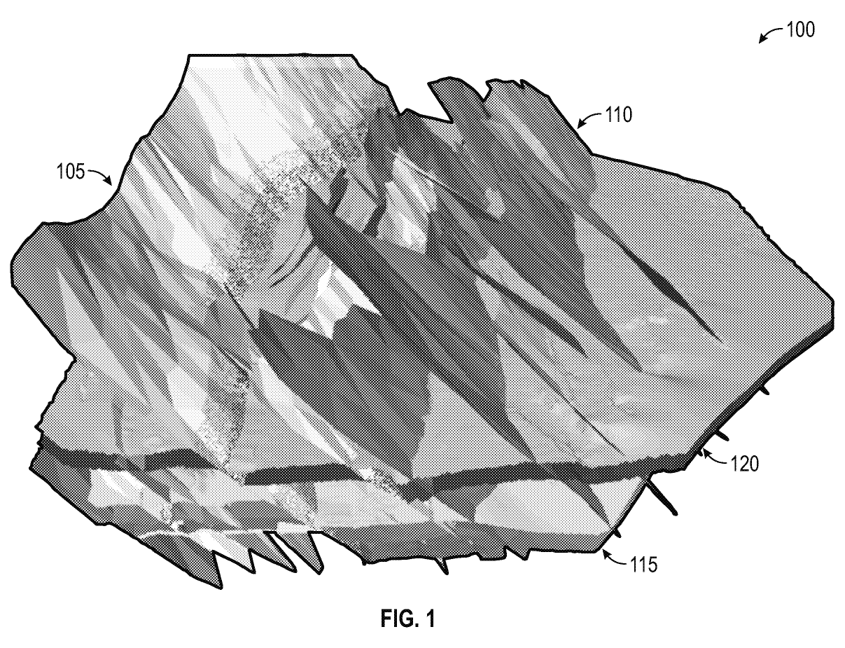

FIG. 1 illustrates an example model 100 of subsurface reservoir. The model 100 may represent the various horizons and faults that exist in the subsurface ground. The faults may represent a planar fracture or discontinuity in a volume of ground across which there has been displacement as a result of earth movements. The horizons may be either a bedding surface where there is marked change in the lithology within a sequence of sedimentary or volcanic rocks, or a distinctive layer or thin bed with a characteristic lithology or fossil content within a sequence.

The locations of the horizons 115 and 120 and faults 105 and 110 may be estimates of the locations of the horizons and faults. For example, the location depicted in the model 100 of fault 105 may be within several hundred meters of the actual location of the fault in some places. As another example, the location depicted in the model of the horizon 115 may be within several hundred meters of the actual location of the horizon in some places. In some implementations, the location depicted in the model 100 of a fault or a horizon may not correspond to an actual fault or horizon. In some implementations, an actual fault or horizon may be present and not depicted in the model 100.

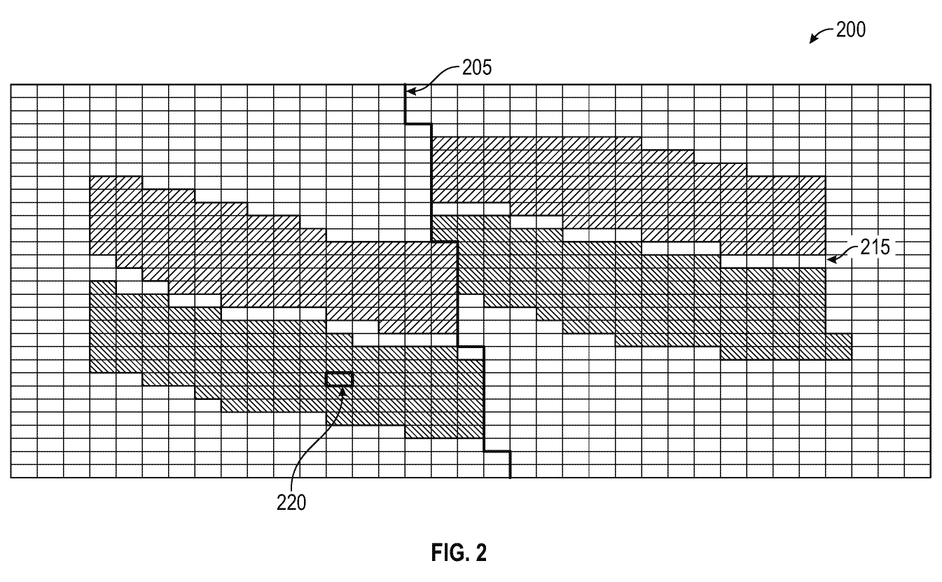

FIG. 2 illustrates an example grid 200 of a two-dimensional representation of a subsurface reservoir. The grid 200 may represent a cross section of the model 100 of subsurface reservoir. The cross section may not necessarily align with any of the horizons or faults. In some implementations, the cross section may be perpendicular to a surface above the subsurface reservoir. The details describing the generation of the grid 200 will be described in more details below.

The grid 200 may include multiple regular cells. The regular cells may be hexahedrons and may all be the same size. In some implementations, the regular cells may be rectangular prisms or cubes. Each cell may share each of its faces with a different neighboring cell, with the exception of cells on the boundary of the grid 200. When viewing a two-dimensional cross section of the grid 200, the cells may appear as quadrilaterals. In some implementations, the cells may be rectangles or cubes. Cell 220 is an example cell in the shape of a rectangle.

The grid 200 may include locations of faults and horizons. For example, fault 205 may be located between cells of several neighboring columns. As another example, horizon 215 may be located between cells of various neighboring rows. The cells that are next to a fault or a horizon may be the same size and shape as the other cells in the grid 200. The grid 200 may cause the faults and horizons to be rasterized to align with the cells of the grid 200.

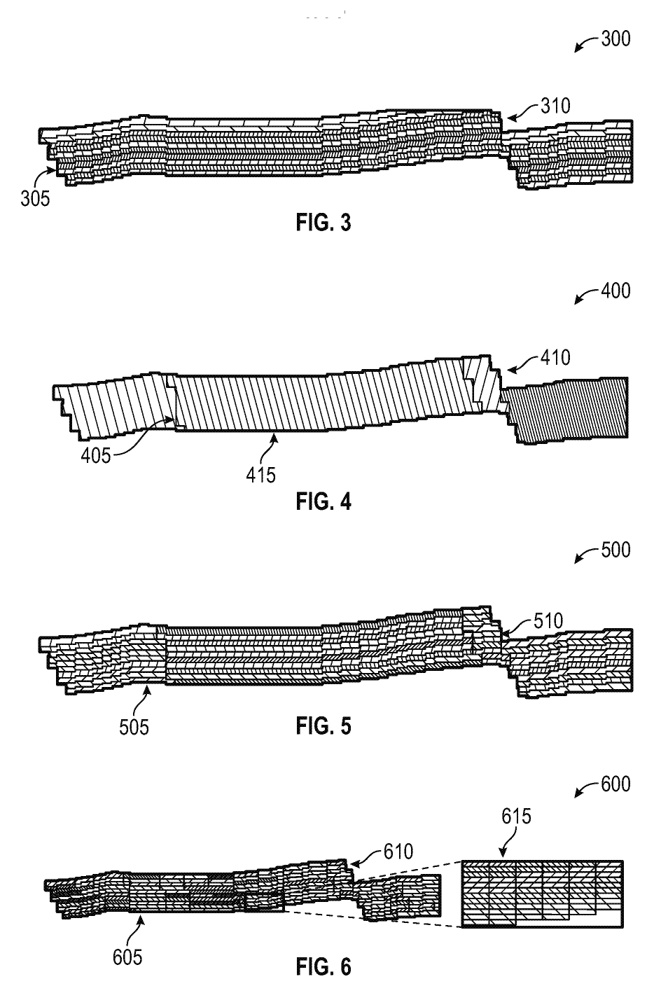

FIG. 3 illustrates an example grid 300 divided into strata. The strata may represent the layers between the horizons of the subsurface reservoir as represented by the grid. The grid 300 may include multiple strata such as example strata 305. Because each stratum comprises individual cells, the edges of the strata are not smooth. Instead, the edges of each stratum align with the edges and faces of the cells of the grid 300. The grid 300 may also include a representation of a fault 310. Fault 310 may also not be smooth because the edges of the fault 310 align with the edges and faces of the cells of the grid 300. The grid 300 may be divided using input horizon surfaces and may be subdivided into proportional or top/base conformable layers.

FIG. 4 illustrates an example grid 400 divided into segments. The segments may represent the portions of the subsurface reservoir between the faults as represented by the grid 400. The grid 400 may include multiple faults. The faults may be major or minor faults and may act as baffles or barriers to flow. Because each segment comprises individual cells, the edges of the segments are not smooth. Instead, the edges of each segment aligns with the edges and faces of the cells of the grid 400. Segment 415 may be bordered by fault 405 and another fault. Fault 405 and fault 410 may be example of faults illustrated in the grid 400. Fault 410 may represent a discontinuity in the horizons. Fault 405 may represent continuity in the horizons.

FIG. 5 illustrates an example grid 500 divided into model structural units (MSUs). The MSUs are a combination of the strata and segments. In other words, the MSUs are divided by the horizons and faults. Similar to the segments and strata, the MSUs comprise individual cells. Because of this, the edges of the MSUs are not smooth. MSU 505 and MSU 510 may illustrate example MSUs. Both MSU 505 and MSU 510 have edges that are not smooth because the edges are made up of the edges and faces of individual cells.

FIG. 6 illustrates an example grid 600 divided into MSUs that is prepared for reservoir simulation. The MSUs of the example grid 600 may be a combination of the strata and segments. For example, MSUs 605 and 610 may be a combination of neighboring faults and horizons. FIG. 6 includes an inset 615 that illustrates the individual cells of various MSUs. Each of the individual cells in the inset 615 are the same size, such as rectangles of the same size. The inset 615 illustrates the individual cells in two dimensions, but similar features and qualities exist when extending to a third dimension. For example, the cells may be rectangular prisms of the same size in three dimensions.

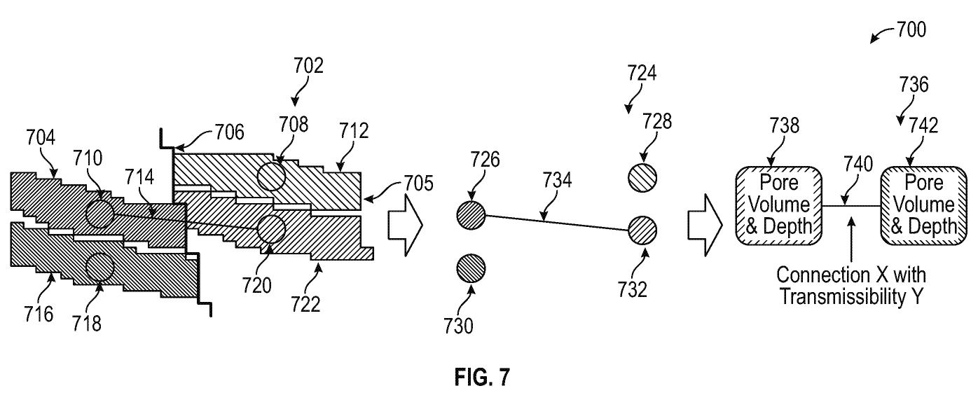

FIG. 7 illustrates an example transition 700 from a grid to a representation of the grid. The transition 700 may be used to prepare the data from the grid for input into a simulator. The simulator may be configured to predict likely changes to the reservoir over a given period of time.

The transition 700 includes a grid stage 702. The grid stage 702 may include several cell groups 704, 712, 716, and 722. The cell groups 704, 712, 716, and 722 may be similar to model structural units or may be abstract dynamic cells that will be discussed below. Each of the cell groups 704, 712, 716, and 722 may comprise individual cells that are of equal size. For example, the individual cells may be rectangles in a two-dimensional representation or rectangular prisms in a three-dimensional representation. The grid stage 702 may also include a representation of a fault 706 and a horizon 705. Each of the cell groups 704, 712, 716, and 722 may be represented by a node 710, 708, 718, and 720, respectively. Because cell group 704 and cell group 722 share a border with fault 706, the node 720 and the node 710 may be connected by edge 714 to represent the ability of a fluid or other material to move between the underground area represented by cell group 704 and cell group 722.

The network stage 724 may include the nodes and edges from the grid stage 702. The cell groups 704, 712, 716, and 722 may not be needed at this point. The node 726 may correspond to node 710. The node 732 may correspond to node 720. The node 730 may correspond to node 718. The node 728 may correspond to node 708. Edge 734 may correspond to edge 714.

In the metadata stage 736, each of the nodes and edges may be assigned various values. The nodes may be assigned a pore volume, a depth, a pressure, and a saturation. The edges may be assigned a transmissibility between the two nodes. The description related to the determination of these values will be discussed in more detail below. As an example, node 738 may correspond to node 726 and include values for a pore volume and depth that correspond to the underground area represented by cell group 704. As another example, node 742 may correspond to node 732 and include values for pore volume and depth that correspond to the underground area represented by cell group 722. As another example, edge 740 may correspond to edge 734 and include a value for the transmissibility between node 738 that represents the underground area represented by cell group 704 and node 742 that represents the underground area represented by cell group 722. Nodes 728 and 730 from the network stage 724 may also include values for pore volume and depth.

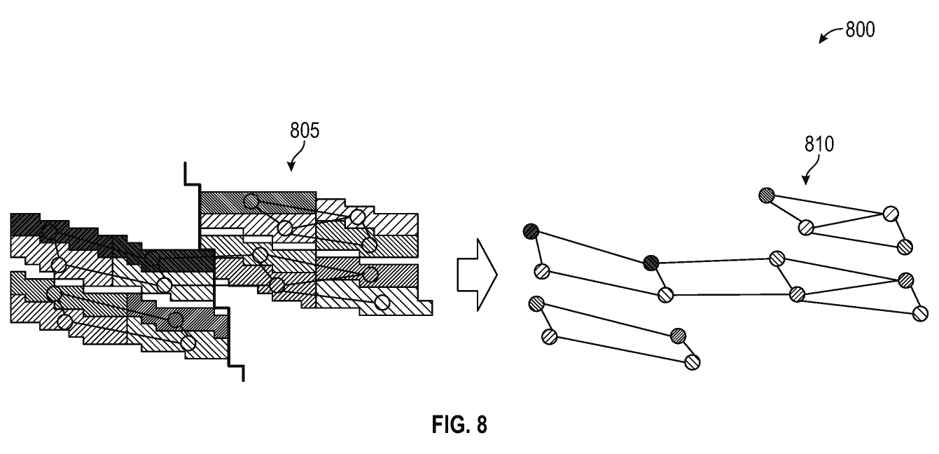

FIG. 8 illustrates an example transition 800 from a grid to a representation of the grid. The transition 800 may be used to prepare the data from the grid for input into a simulator. The simulator may be configured to predict likely changes to the reservoir over a given period of time. The transition 800 may be similar to the example in FIG. 7, but on a larger scale.

The grid stage 805 may include various cell groups. The cell groups may be similar to model structural units. Each cell group may correspond to a node. For the cell group pairs that share borders and/or are able to have fluid flow between the cell group pairs, an edge may connect those cell groups.

The network stage 810 may include the nodes and edges from the grid stage 805. The cell groups may not be needed at this point. Some groups of nodes may not be connected to other groups of nodes because fluid may not be able to flow between the corresponding underground areas represented by cell groups. The nodes may each be assigned a pore volume, a depth, a pressure, a saturation, a flow, and/or any other similar value. The edges may be assigned a transmissibility and/or any other similar value.

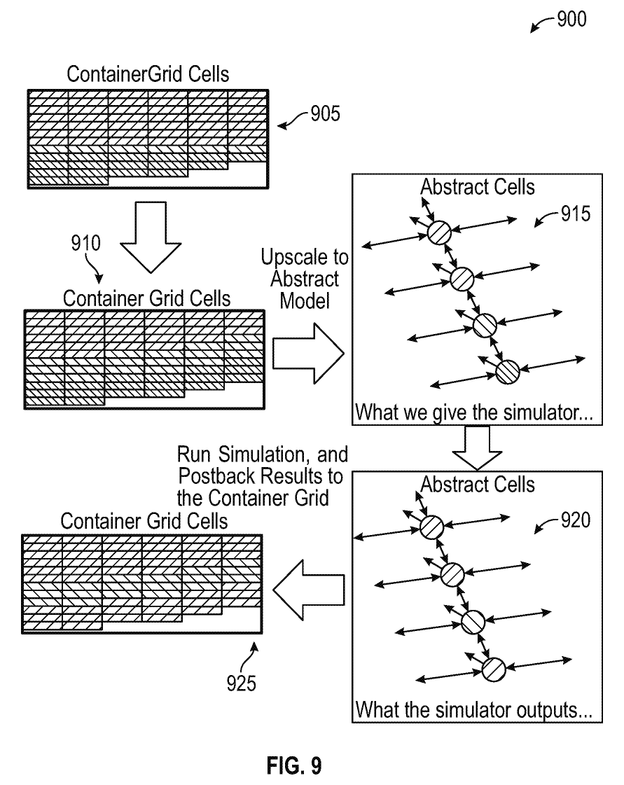

FIG. 9 illustrates an example interaction 900 between a simulator and networks representing cell groups. The interaction 900 may include illustrations of the grids with groups of individual cells and networks representing groups of the cells.

The flow of interaction 900 begins with grid 905. The grid 905 represents a portion of a larger grid and the individual cells in the grid 905. The different shading or patterns on the grid 905 represents different values such as pore volume, depth, pressure, saturation, and/or any other similar value. In some implementations, the different shading may represent the amount of a fluid in the cell, such as water. The cells of the grid 905 may be equal size, such as a rectangle.

The interaction 900 continues to grid 910. The grid 910 may include a representation of the grid 905, with cell groups added to the grid 910. The shading or patterns of the grid 910 may represent various MSUs or abstract dynamic cells. The MSUs of the grid 910 may be based on the grid 905. Each MSU may be assigned a group of cells. Each MSU may have its own pore volume, pressure, depth, saturation, and/or any other similar value. These values may be based on the values of the individual cells that comprise the MSU.

The interaction 900 continues to network 915. The network 915 is a node and edge representation of the grid 910. Each node corresponds to an MSU of grid 910, and each edge may correspond to a fluid connection between MSU pairs. Each node may include a pore volume, pressure, depth, saturation, and/or any other similar value that corresponds to the MSU. Each edge may include a transmissibility between the MSU pairs that correspond to the connected nodes. Each node and edge may also have a unique identifier that may correspond to the unique identifier of the corresponding MSU or fluid connection. The network 915 is provided to the simulator along with an amount of time for the simulator to simulate fluid movement in the underground reservoir that corresponds to the grids 905 and 910 and the network 915.

The interaction 900 continues to network 920. The network 920 may be output by the simulator upon receiving the network 915 and an amount of time. The network 920 may represent the state of the MSUs that correspond to the underground reservoir after the amount of time has passed. The network 920 may represent a likely condition of the fluid movement in the underground reservoir in the future after the amount of time has passed. The shading of the nodes may represent the movement of the fluid. The nodes of the network 920 may have new values for the pore volume, pressure, depth, saturation, and/or any other similar value that are output by the simulator. The edges of the network 920 may have new values for the transmissibilities and/or any other similar value that are output by the simulator. In some implementations, some of these values may be unchanged.

The interaction 900 continues to grid 925. The grid 925 may include the MSUs of the grid 910 with the values output from the simulator. The values output by the simulator may be included in the network 920. The shading of the grid 925 may represent the changes in the pore volume, pressure, depth, saturation, and/or any other similar value. The MSUs of the grid 925 are the same as the grid 910. In other words, the MSUs of the grid 910 were converted to the network 915. The network 915 was provided to the simulator, and the simulator output network 920. The values from the network 920 were posted back onto the original fine-scale regular grid for analysis and visualization.

### Use of a Regular Grid in Reservoir Modelling Workflows

One of the steps in modeling underground reservoirs using the techniques described in the specification involves the use a regular grid as part of computer code for an automated workflow for building reservoir simulation models. This forms part of the method described above.

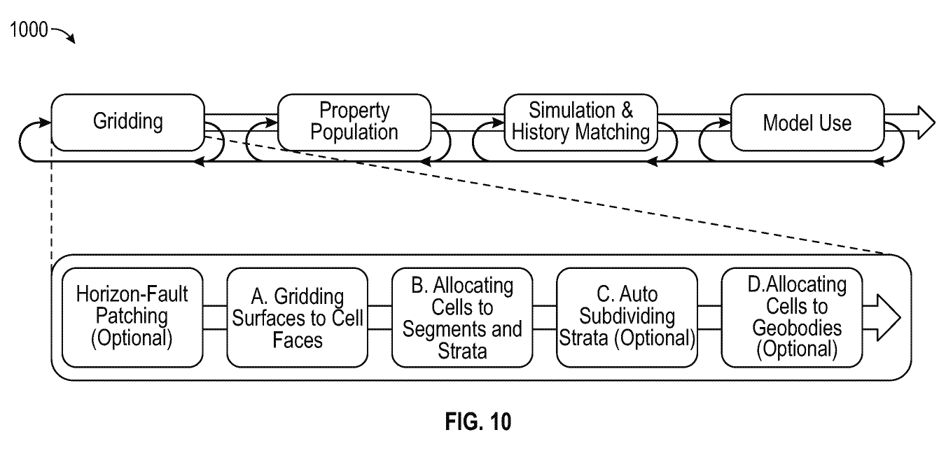

FIG. 10 illustrates an example workflow 1000 for accelerated reservoir modelling using regular and abstract grids with gridding stage. Numerical reservoir models use a method of gridding to divide the continuous volume of subsurface rock into cells. The properties of the rock are considered to be homogeneous within a cell, for the purposes of subsequent mathematical calculations which determine the volume of fluids in place in the pore spaces of the rock, and how those fluids are expected to move between cells when wells drilled into the rock are opened to flow. As the amount of computation needed to simulate flow is much greater than that needed for static volumetric calculations, an example technique involves a fine cellular model, which may be referred to as a geomodel, to be constructed and used for static volumetric calculations, with a coarser cellular model, sometimes with larger cells, being derived from it for flow simulation purposes. The innovation described in this specification relates to a form of the fine cellular model.

Some example modelling methods use an irregular pattern of cells during gridding. The cell faces are constructed to align with geological surfaces such as horizons that may be between geological strata and faults. Cells may be hexahedral, though other shapes may be used. When hexahedral cells are used, cells are typically indexed by three integers referred to as I, J, and K. K indices may vary with depth or are orthogonal to the geological strata, whilst I and J vary in the plan view or across the areal extent of strata.

The advantage of using irregularly shaped cells is that the faces can be aligned with changes in geological properties, so that the assumption of homogeneous properties within each cell is likely to be more valid. Also, because fluids can typically flow more easily in the plane of a geological stratum than in the perpendicular direction, the mathematical representation of this rock permeability can be simpler if the cells align with the stratigraphy. However, the use of irregular cells is not suitable for a highly automated workflow. This is mostly due to the gridding methods being prone to generating cells with unphysical geometries, such as having a “bow-tie” shape, or a negative volume. Such errors in gridding need to be resolved before the model can be used, and this step requires much intervention by a user. This also makes it impractical to model the full range of uncertainty in the geological structure, for example, uncertainty in the depths of horizons, or more major differences in possible interpretations of seismic data.

The method discussed in this specification uses a completely regular hexahedral grid, sometimes called a voxel grid or a lattice grid, for the fine cellular grid. An intermediate form of grid called a block grid is another example grid. However, such block grids differ from completely regular grids by having variable depths to the tops of columns of cells, variable thicknesses to cells, and sometimes an irregular “tartan” pattern to the columns of cells in plan view.

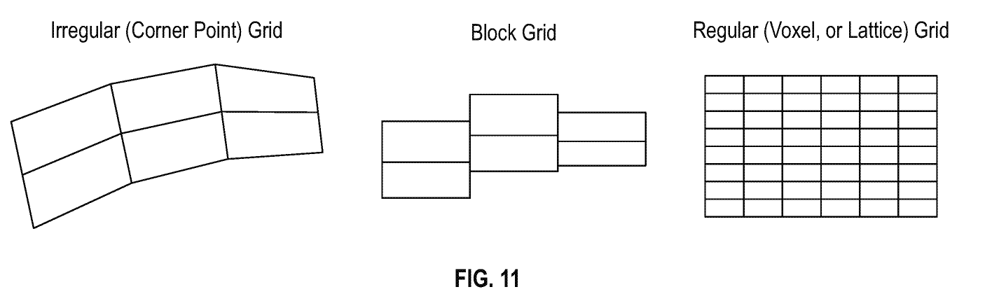

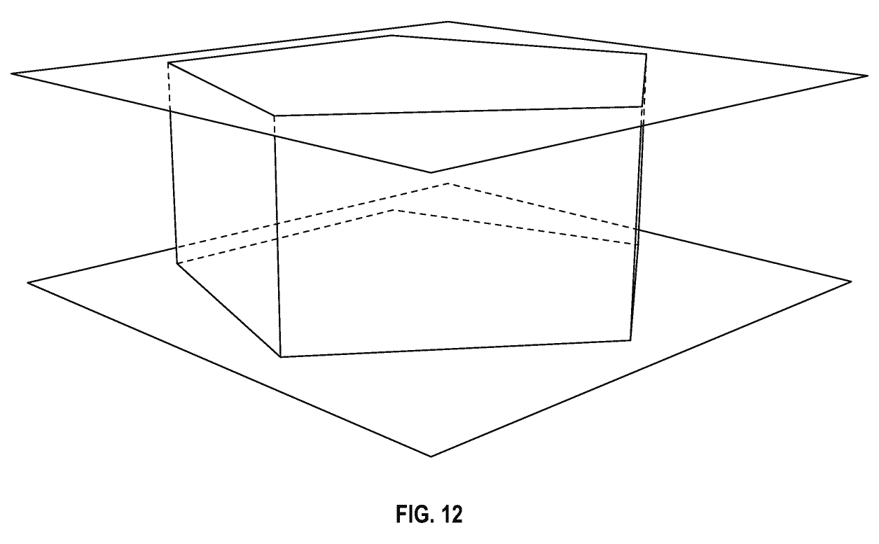

FIG. 11 illustrates a comparison of irregular grid (corner point), block grid, and regular grid. The use of regular grids avoids issues of cells having an unphysical geometry, and hence is suitable for a highly automated workflow. The gridding step becomes a matter of mapping geological surfaces onto the faces of the regular cells. Although this is a computationally intensive step, the regularity of the grid allows for a highly efficient, optimized algorithm to be applied.

The gridding algorithm is suitable for implementation on either central processing units (CPUs) or graphical processing units (GPUs). The gridding algorithm allows for several advantages. First, the gridding algorithm allows for a highly automated workflow with minimum human intervention. Second, the gridding algorithm allows for use of very fine cells, which offsets errors in bulk rock volume introduced by the quantization. Third, the gridding algorithm allows for ease of re-running the modelling workflow with a modified cell size as needed. Fourth, the gridding algorithm allows for ease of modelling uncertainties in the geological structure by gridding different sets of representations of the geological surfaces.

As well as horizons and faults, other surfaces can also be gridded in the same way. These might include geobody boundaries, which may be represented by a top and base surface pair, administrative boundaries such as a national border, projected vertically to form a “curtain” surface, and/or a vertical projection of a polygon defining the area of interest of the model, sometimes called a frontier boundary.

After gridding, the regular grid cells are allocated to model structural units depending on their position relative to the gridded surfaces. The model structural units represent known parts of the geology, typically the intersection of a geological stratum with a particular fault block. This allows appropriate values to be assigned to the cells for properties such as net-to-gross ratio, porosity, and permeability. The method of allocating cells to model structural units is also detailed below.

### A. Algorithm for gridding surfaces to cell faces

FIG. 12 illustrates an example scene with frontier polygon, curtain, and ceiling and floor planar surfaces. The first step is to define the volume to be covered by the regular grid, referred to in this specification as the container. The container is defined by a plan view frontier polygon defining the area of interest, together with a depth range defined by a shallower ceiling depth and a deeper floor depth. The container volume is bounded by a curtain surface projected vertically from the frontier polygon, and a pair of horizontal planes at the ceiling and floor depths respectively. The dashed lines are behind one or more of the polygon, curtain, ceiling, and/or floor surfaces.

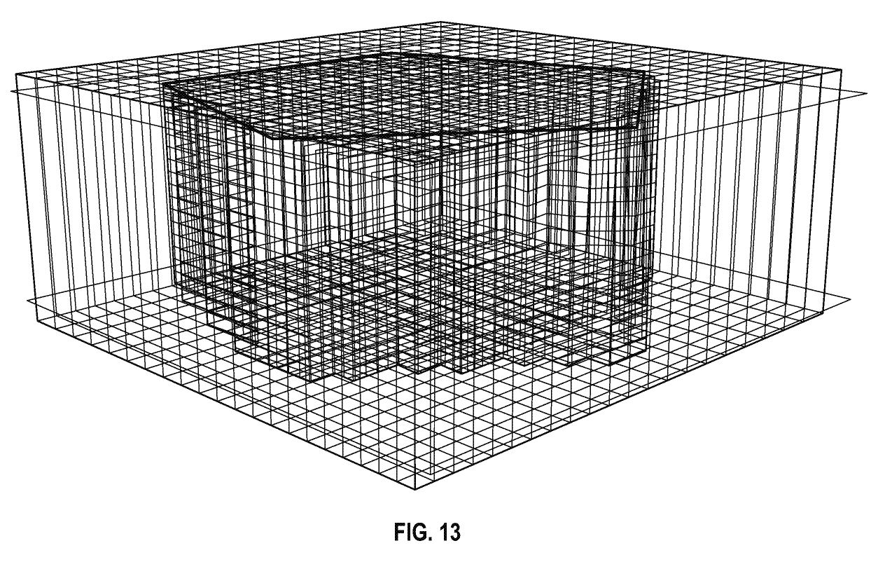

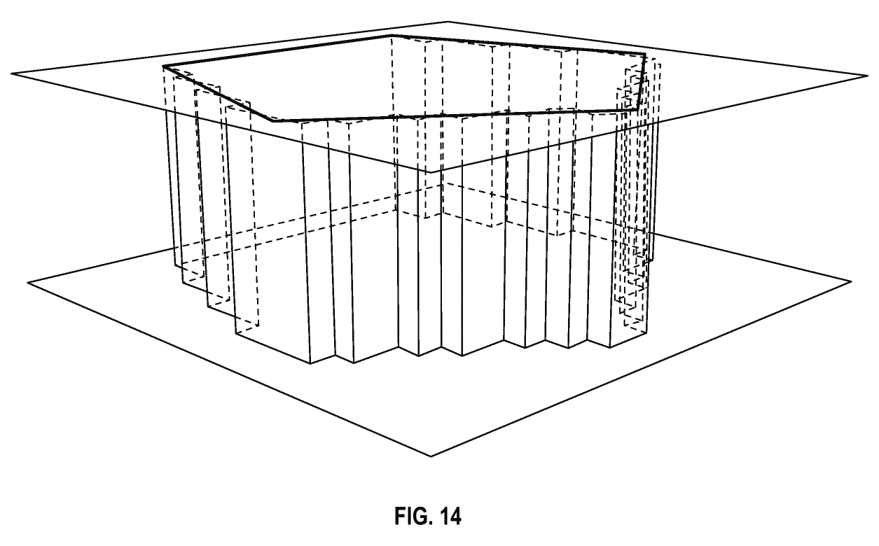

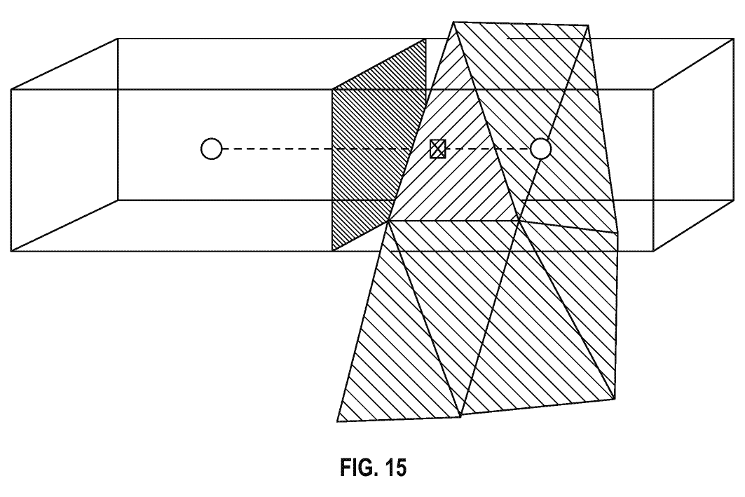

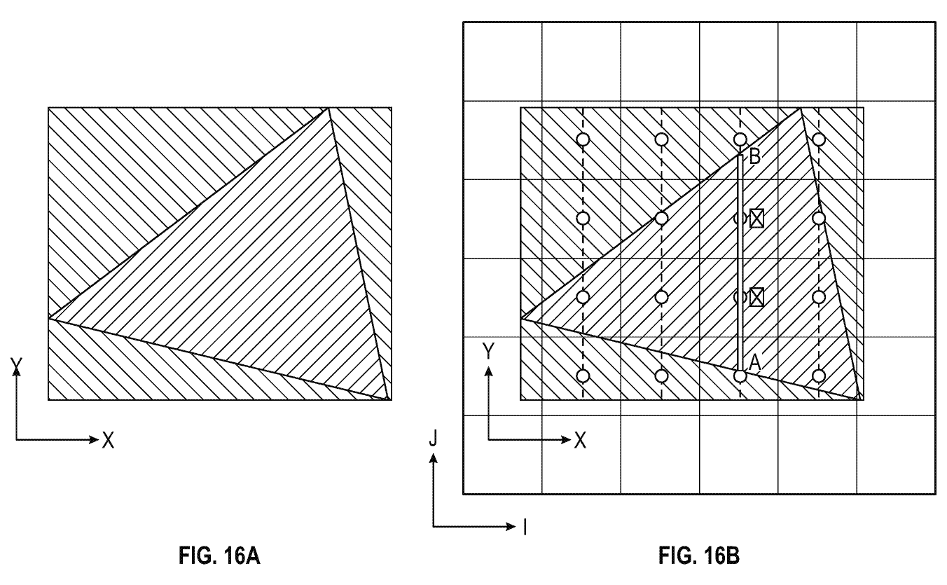

FIG. 13 illustrates an example regular grid superimposed over the container space, with frontier polygon. FIG. 14 illustrates an example container with the frontier curtain gridded onto cell faces. Having established the container, a regular grid is constructed which completely covers the container volume. This regular grid is referred to as the container grid. It can easily be automatically regenerated for a different size of cell. The orientation of the container grid in plan view may be explicitly defined or determined automatically so as to minimize the plan view rectangular area of the grid whilst still enveloping the frontier polygon. The K axis is vertical. The dashed lines are behind one or more surface.

The extent of the grid is such that a slice of unused cells is included beyond the container in all six directions. This simplifies coding elsewhere as each cell within the container is guaranteed to have neighboring cells on each of its faces.

A local coordinate reference system (known as the container grid CRS) is established with an origin at the corner of the grid, and with x, y and z axes aligning with the I, J and K axes of the grid. Use of a local CRS is not uncommon in cellular models, as it reduces the magnitude of the coordinates when compared with a more global CRS. That in turn reduces the build up of rounding errors in calculations involving the coordinates. In this specification, the alignment of the container grid CRS with the grid’s axes, together with the regularity of the grid, allows for the significant optimization of the gridding algorithm, greatly reducing the computation needed. The relationship between the container grid and its CRS also means that the geometry of the grid may not need to be explicitly represented in an expanded form, which significantly reduces the memory and disk storage requirements.

Having established the container grid, the gridding of horizon, fault and other boundary surfaces can be carried out. Each surface is gridded independently of the others, so the processing can happen in parallel. The surface is converted to a triangulated set, if it is not already in that form. It is also transformed into the container grid CRS. A set of cell faces is then identified to represent the surface in the grid. A face is included in the set if the straight-line segment between the centers of the two cells either side of the face intersects any of the triangles in the triangulated set representation of the surface.

FIG. 15 illustrates an example section of grid with a straight line between cell centers shown intersecting a triangle in a surface. The cell face shared between the two cells may be included in the gridded representation of the surface.

Each of the three dimensions (I, J, K, which align with x, y, z) may be processed separately, creating sets of I, J and K faces. These three sets are then combined to give the full set of faces representing the surface.

Each triangle in a surface’s triangulated set should to be considered in turn. To make use of multiple threads (a low level form of parallel processing), the set of triangles is divided into batches, with each batch being processed by its own thread. For each triangle, a bounding two-dimensional rectangle is found from the coordinates of the vertices of the triangle, omitting the axis of view. For example, when searching for K faces, an x-y bounding rectangle is constructed (aligned with the I & J axes), ignoring the z values in the triangle vertex coordinates. The discussion below also refers to the example of K faces, with identical logic being applicable to the search for J faces and I faces.

FIG. 16A illustrates an example projection of a triangle in the plan view, with x-y bounding box shown. FIG. 16B illustrates an example triangle with regular grid overlaid, where I and J axes align with x and y and cell center points are shown as dots. One I line is bolded, with intersection of triangle edges at A & B, and a pair of triangle intersection points indicated by x’s.

The bounding rectangle is converted into a range of cell indices for the two dimensions being covered. For example, for K faces, the x-y ranges are converted to I and J integer ranges, based on the center points of cells being within the rectangle. This conversion may benefit from the alignment of the IJK axes with the xyz axes and the regularity of the grid.

One of the two dimensions is used to construct a set of parallel lines within the bounding rectangle, with one such line for each distinct cell center point value in that dimension. For example, for each distinct I value, a line is constructed with constant x. This line is intersected with whichever two of the three edges of the triangle, in the x-y projection, it crosses. The full three-dimensional xyz coordinates of these two intersection points are carried forward. The two y values of the intersection points give a limit to the J range of cell centers within the projected area of the triangle. For each of the cell centers within that limited range, the intersection “depth” (“into the page”) is found by a linear interpolation from the two intersection points. In this example, the z coordinates of each intersection point are found by the interpolation. These values are then converted to the index of the nearest face in the direction of view, giving a K face index to go with the I and J indices already determined, bearing in mind that the faces are half way between the cell centers.

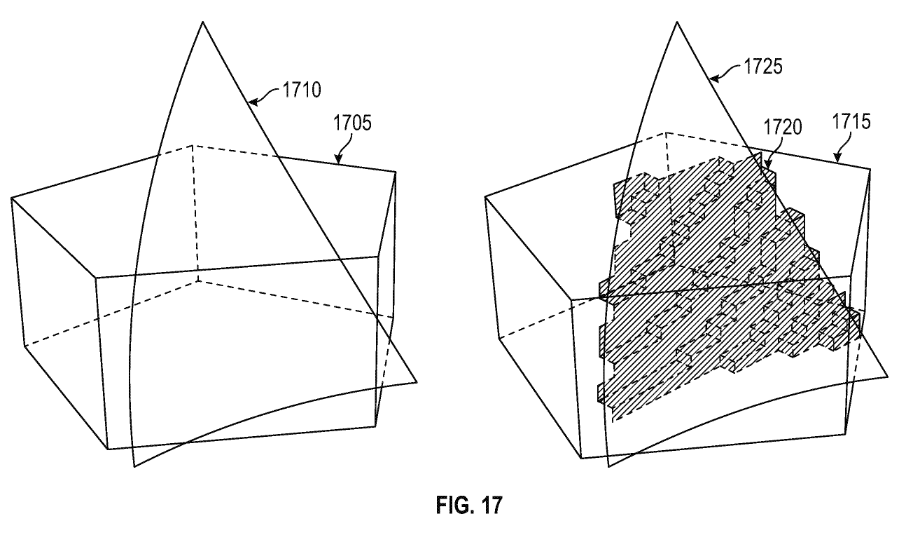

The logic is repeated for each J value within the limited range, then for each I line within the bounding rectangle. The procedure is carried out for each triangle in the triangulated set, and all of that is applied in each of the three dimensions to give the full set of container grid faces to represent the surface. FIG. 17 illustrates an example triangular surface 1710 together with a grid frontier curtain 1705 and an example triangular surface 1725 with the gridded cell faces 1720 overlaid together with a grid frontier curtain 1715.

### B. Algorithm for allocation of cells to segments and strata

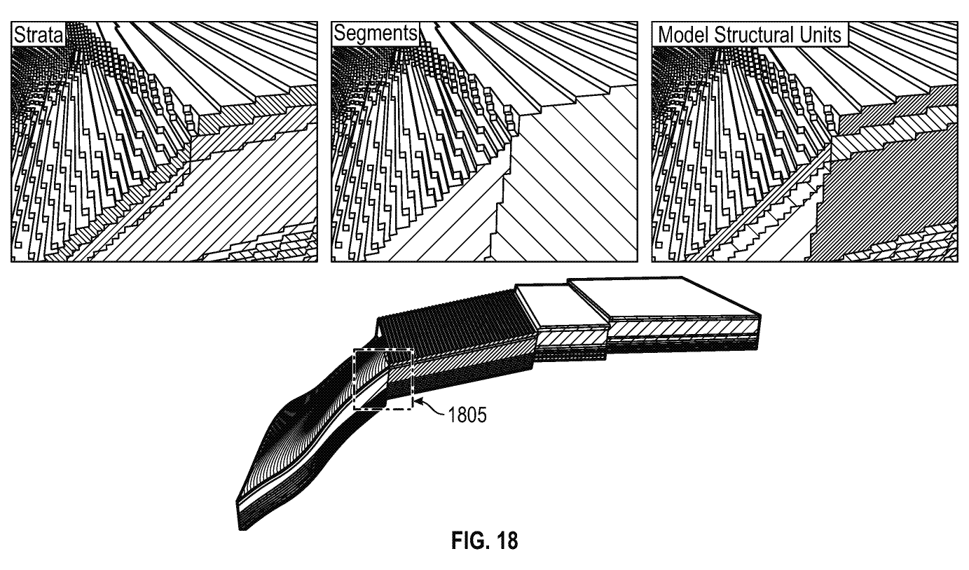

After the gridding algorithm has been applied to the surfaces, each container grid cell is allocated to a segment (fault block or similar) and to a geological stratum. The intersection of a stratum and a segment defines a model structural unit. The allocation to a segment depends on the location of the cell center relative to the gridded face sets for the faults, the frontier, and other administrative boundaries if present. The allocation to a stratum depends on the location of the cell center relative to gridded faces for the horizons. FIG. 18 illustrates example cells divided by strata, segments, and model structural units for the inset 1805.

For the allocation to be reliably automated, some processing is carried out on the surfaces before they are gridded. Firstly, the fault surfaces are extended with extra triangles so that they reach the edges of the grid. That step ensures that the faces gridded for each fault will form an unbroken set that divides the container grid into two parts. The horizons are also processed before gridding. “Tears” (e.g., untriangulated areas) in the horizon surfaces at faults may be filled in with a patch of extra triangles which follow the fault surface. Alternatively, each separate patch in the horizon surface (separated by a tear) may be extended individually to overlap adjoining patches. This patching ensures clean joins between horizons and faults.

After being patched to the faults, the horizons are also extended with extra triangles to reach the edge of the grid. For both faults and horizons, a property is created to keep track of which triangles relate to the interpreted surface area and which to the extension of the surface.

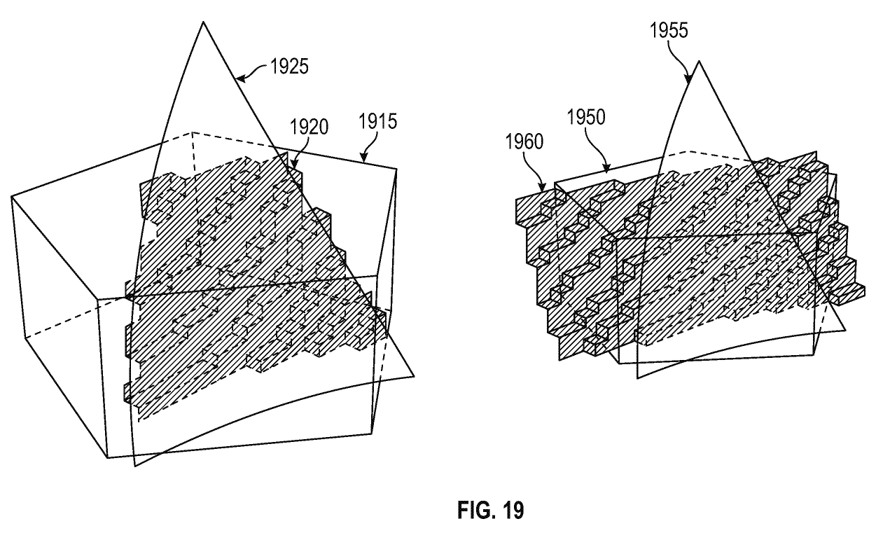

FIG. 19 illustrates an example triangular surface 1925 with the gridded cell faces 1920 overlaid together with a grid frontier curtain 1915 and an example extended surface 1955 with the corresponding gridded cell faces 1960 reaching the edge of the regular grid with a grid frontier curtain 1950. The lighter patterns and/or the dashed lines are behind the triangular surface 1925 or the extended surface 1955 or another surface.

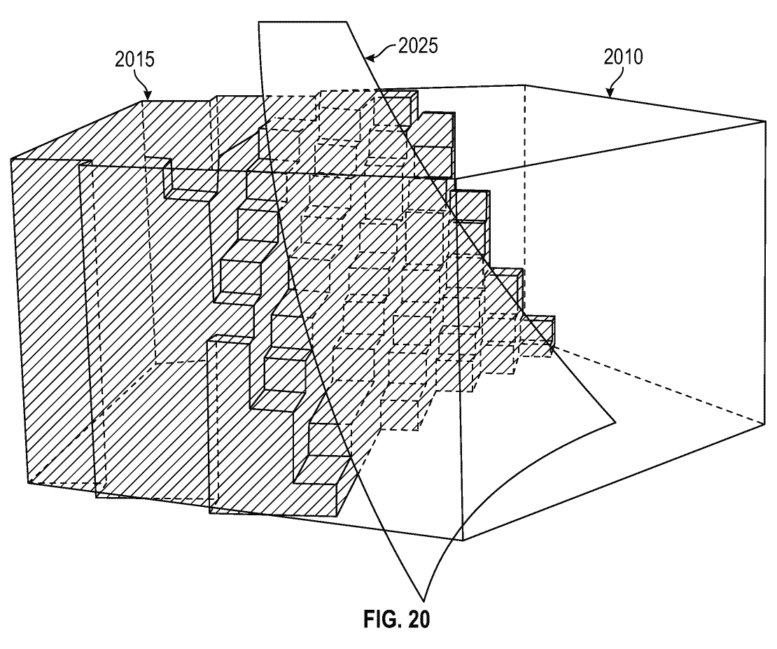

After gridding, for each surface, a Boolean bisector property is created on the cells of the container grid, indicating which side of the gridded face set each cell is positioned. This bisector is generated by initializing a property array to false, or zero, except for a single cell in one corner of the grid which is set to a value of true, or one. The true values are then repeatedly spread to any neighboring cells where the intervening face does not form part of the gridded face set. FIG. 20 illustrates an example grid frontier curtain 2010 with cells 2015 allocated to true and the original surface 2025. The lighter patterns and/or the dashed lines are behind the surface 2025 or another surface.

To allocate cells to segments, an integer segment identifier property is first initialized to a fixed value of one for all cells within the container volume. Cells outside the container may be set to a null value. Each fault, or administrative boundary, bisector is then considered in turn. The order in which the fault bisectors are applied is determined by a segment scheme which is prepared beforehand. The segment scheme also defines which parent segment each fault divides.

Having determined the next fault to be processed, the cells are identified which are currently allocated to the parent segment being divided. No other cells may be reallocated during the processing of the fault. A pair of new, unique, child segment identifiers are generated by multiplying the parent identifier by two (shifting left one bit) and adding zero and one respectively. The cells are reallocated to one or other of the child segments based on the bisector property for the fault.

The procedure is repeated for each fault, effectively implementing a recursive binary subdivision of the container grid volume. The segment scheme includes a rank concept that may be analogous to the ranks of a multi-rank stratigraphic column which allows the process to be stopped after faults of a given significance level have been considered.

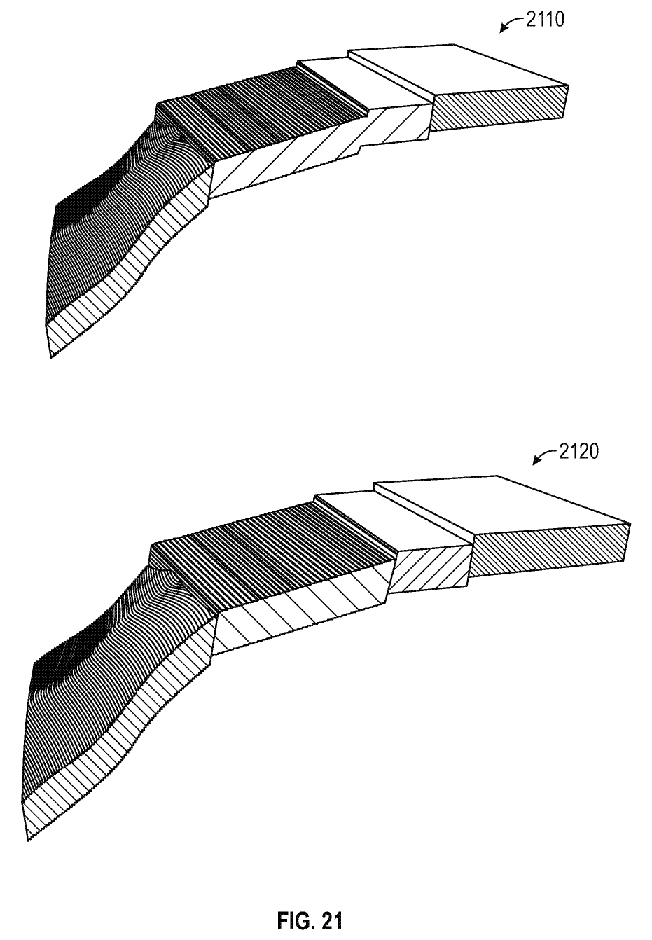

FIG. 21 illustrates an example segment allocation 2110 at a coarse rank that may be a rank 1 with major faults only and an example segment allocation 2120 at a fine rank that may be a rank 2 with major and minor faults.

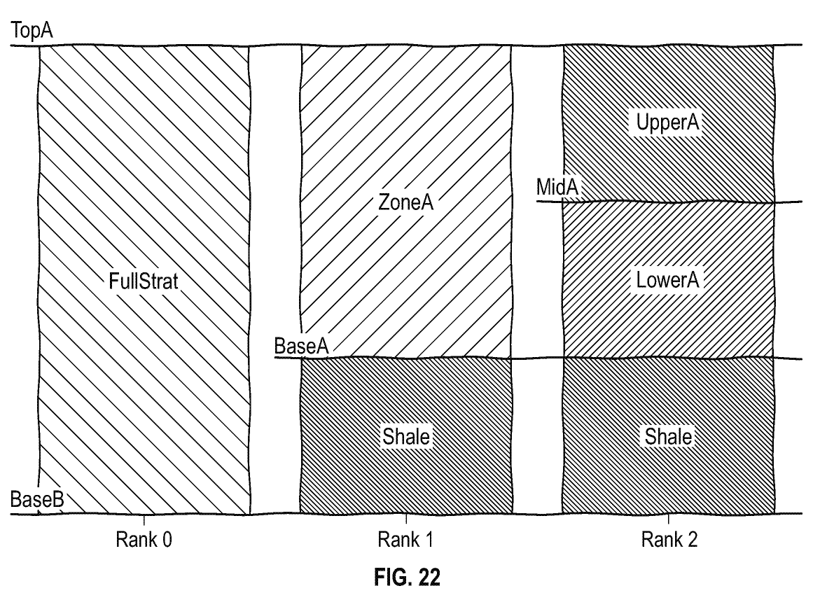

The allocation of cells to strata proceeds in a similar manner. The strata scheme, a multi-rank stratigraphic column, indicates the relationship between strata and horizons. The coarsest rank, rank zero, always consists of a single stratum covering the whole geological interval of interest and is bounded by the oldest (base) horizon and youngest (top) horizon. The stratum identifier array is initialized to a value representing the rank zero stratum by intersecting the bisector properties for these two horizons. The stratum identifier is set to a null value for cells above the top horizon, below the base horizon, or outside the frontier curtain. FIG. 22 illustrates an example multi-rank stratigraphic column, which may be referred to as a strata scheme.

Each finer rank in the strata scheme is then processed in turn. For each stratum in the parent rank, its child strata are determined from the strata scheme, together with the horizons that separate the children. The cells currently allocated to the parent stratum are reallocated to the children based on the bisector arrays for the separating horizons. The child strata are processed in the order oldest to youngest (base to top).

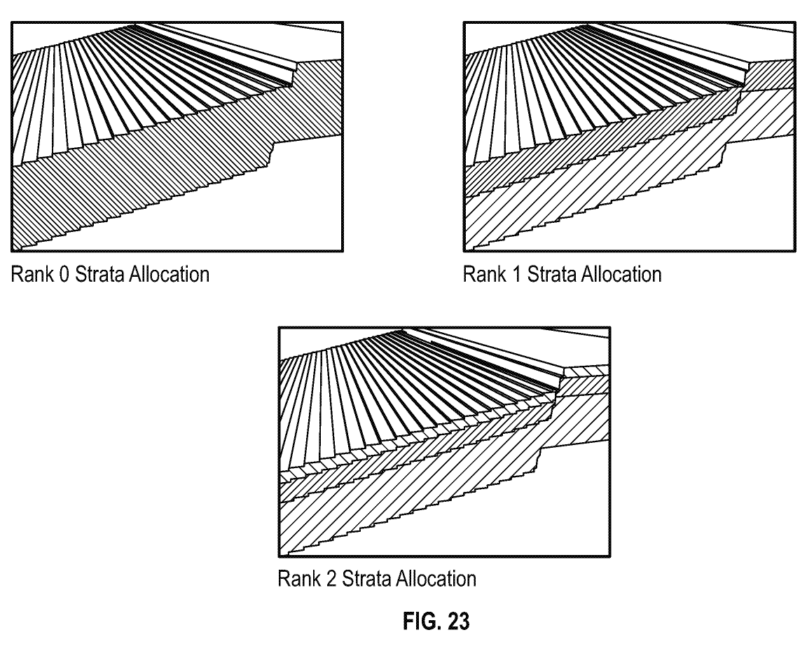

FIG. 23 illustrates an example strata allocation at rank 0, which may be the starting point for the algorithm, at a coarse rank 1 following some division, and at a finer rank 2. After this allocation of cells to strata, there are two options for further processing of the strata allocation: strata auto subdivision and partial allocation to geobodies. These optional steps are described below. When the allocation is complete, including any subdivision or introduction of geobodies, the cells are assigned to model structural units by finding the unique combinations of a segment identifier and a stratum identifier (including any substrata distinction and/or geobody identifier).

The model structural units form the basis of setting geological properties, grouping of cells for building a coarser flow simulation grid, reporting volumetrics, etc. They also allow for meaningful comparisons to be made between different structural scenarios, when the modelling workflow is run multiple times with different sets of representations of the geological surfaces.

### C. Algorithm for auto subdivision of strata

After the allocation of cells to strata described above that may be based on horizons that have a representation as a surface, it may be possible to further subdivide selected strata without the need for intermediate horizons. The subdivision may be made in one of three modes: conforming to top, conforming to base, or proportionally.

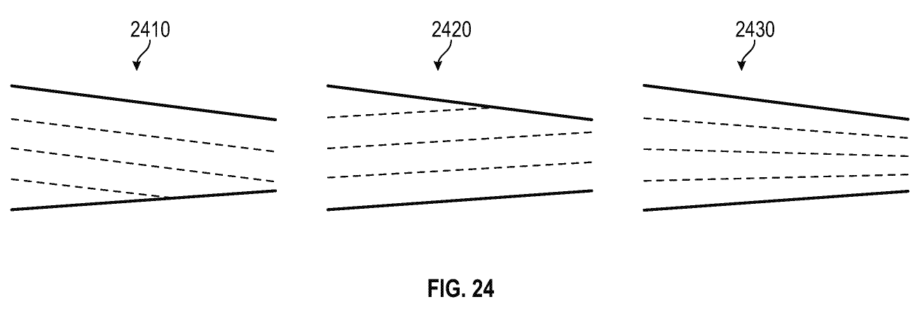

FIG. 24 illustrates example sub-strata with a thinning stratum. Substrata 2410 is conforming to top. Substrata 2420 is conforming to base. Substrata 2430 is proportional.

The subdivision of a particular stratum takes place in the cellular space and is determined segment by segment. This is because the pattern of subdivision within a column of cells depends on the position of K faces assigned to the horizons at the top and the base of the parent stratum. The displacement that may occur at a fault means that such information is only valid in the segment containing the K face and is not applicable to volumes that are on the other side of a fault.

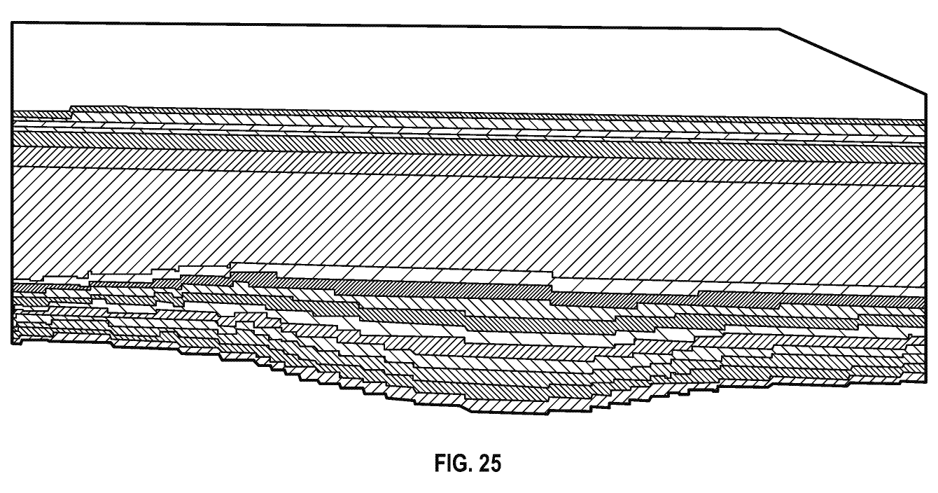

The subdivision of a stratum within a segment is made column by column. The pattern of subdivision is made according to the specification of how the stratum is to be subdivided: which of the three modes of subdivision is to be used, how many substrata to use, and the thicknesses or proportions of the substrata. For each column of cells, the number of cells, for example, the layers, allocated to the parent stratum is also used to determine the pattern of subdivision as it is a measure of the vertical thickness of the stratum at that location. FIG. 25 illustrates an example proportional sub-strata, after allocation to columns of cells, with a variation in the parent stratum thickness.

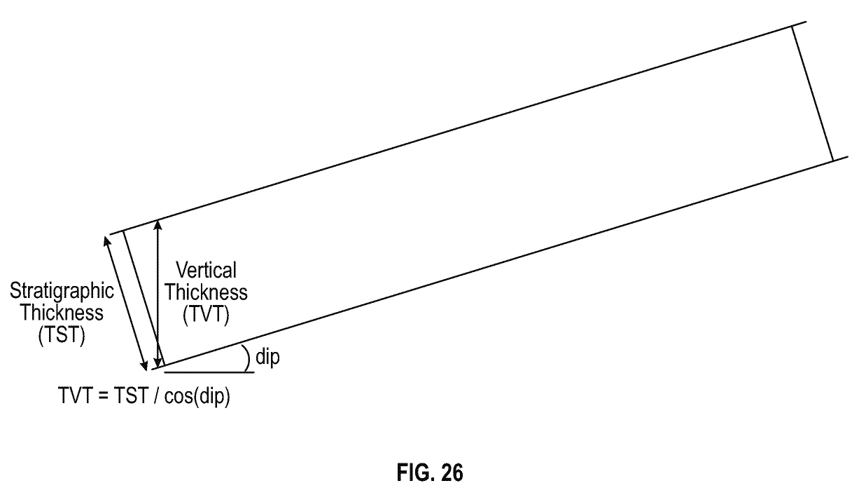

For conforming subdivision, the angle of dip of the stratum at the column that may be determined from the surfaces at the top and base of the parent stratum can also be a factor affecting the pattern of allocation. The thicknesses of the sub-strata defined in the specification of the subdivision are for a horizontal parent stratum (true stratigraphic thickness, or TST). Where the parent stratum is dipping, trigonometry can be used to convert sub-strata thicknesses from TST to true vertical thickness (TVT). The TVT values are calculated on a column-by-column basis and used for the allocation of cells to sub-strata. FIG. 26 illustrates an example dipping stratum and a relationship between true stratigraphic thickness and true vertical thickness.

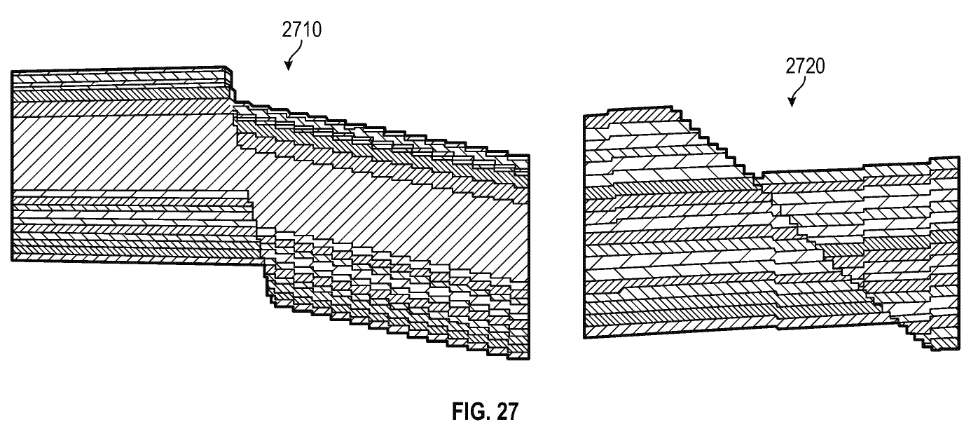

Close to faults, the full parent stratum interval may not be present in a segment. In this situation a K face for either the top horizon, the base horizon, or both, are absent in a column of cells within the segment. Such columns inherit a subdivision pattern from nearby columns where both K faces are present, with the parent stratum full thickness (at time of deposition) assumed to be the same in both column locations. However, the full pattern is truncated, with only a subset of it being used in the column close to the fault. If one of the K faces is present in that column, it is used as a reference point to allocate the subset of the pattern. If neither K face is present in the column, a horizontal replication of the subset of the pattern is used. FIG. 27 illustrates example sub-stratum 2710 and 2720 that are proportional and extrapolated from a full column across to a fault.

### D. Algorithm for allocation of cells to geobodies

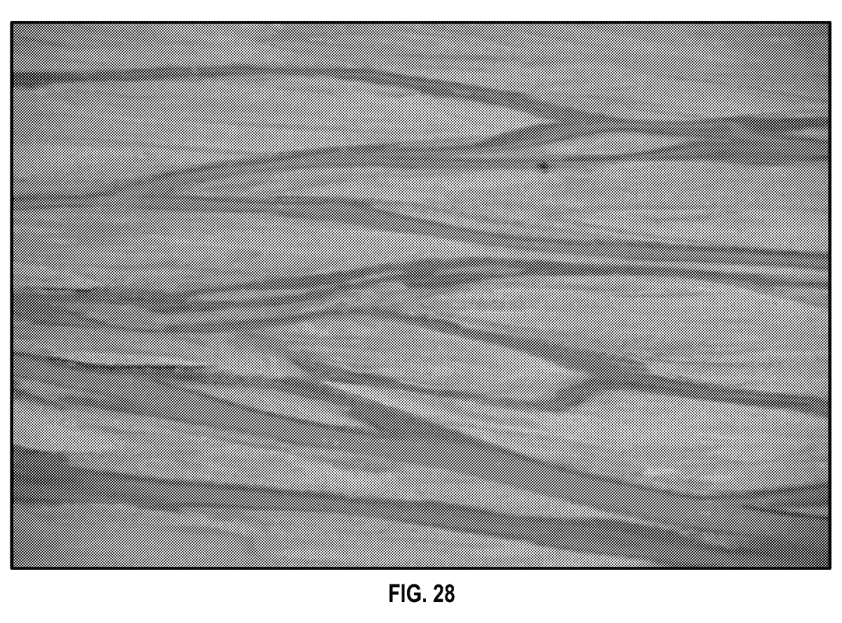

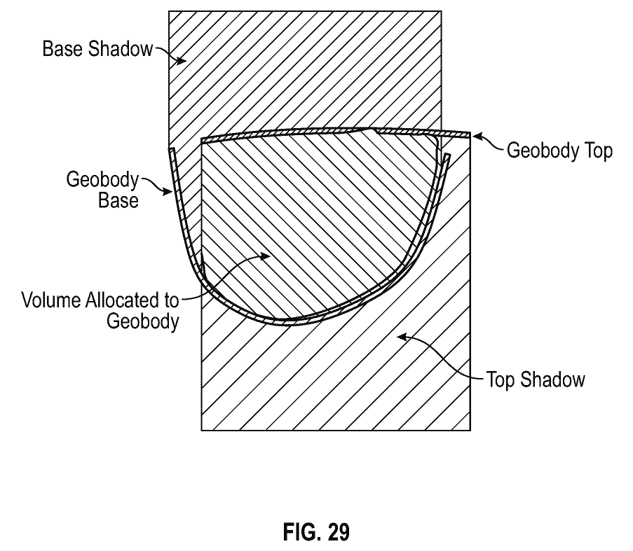

A geobody is a continuous volume of rock, with similar properties, that is not laterally extensive, whereas a stratum is laterally extensive. With regard to reservoir geology, sediments filling fluvial channels, mouth bars and turbidite deposits are some examples of geobodies. FIG. 28 illustrates an example geobody. Braided river channels, if filled with sediment, can result in complex geobodies.

Some modelling workflows include stochastic generation of channel systems, for example. In some example workflows, such stochastically generated data is treated as a rock property and is not covered by the following algorithm. The algorithm described here is for geobodies that have boundary surfaces which have been interpreted from seismic data.

The volume of a geobody is bounded by a pair of surfaces, that may be interpreted from seismic, representing its top and base. Unlike the horizons between strata, these surfaces do not get extended. The geobody surfaces are gridded using the same algorithm as horizon and fault surfaces, as described above. However, no bisector properties are generated for these geobody surfaces.

To determine which cells to allocate to a geobody, a “shadow” Boolean property is generated from the K faces for the top surface of the geobody, set True for any cell beneath such a K face. A similar shadow property is generated from the K faces for the base surface, but as if “lit” from below, so that the property is True for any cell above a basal K face. The intersection of these two Boolean shadow properties identifies the cells which are allocated to the geobody. FIG. 29 illustrates an example schematic showing the downwards shadow from a top geobody surface, the upwards shadow from a base geobody surface, and the intersection of shadows being the volume allocated to the geobody.

In order to handle uncertainty in the interpretation of the geobody surfaces, a geobody scheme is created, analogous to the strata scheme. The geobody scheme may have multiple ranks, with major, usually larger, geobodies being assigned to a coarse rank and less significant, usually smaller, geobodies being at a finer rank. As with strata and segment schemes, processing can be limited to a particular rank if desired.

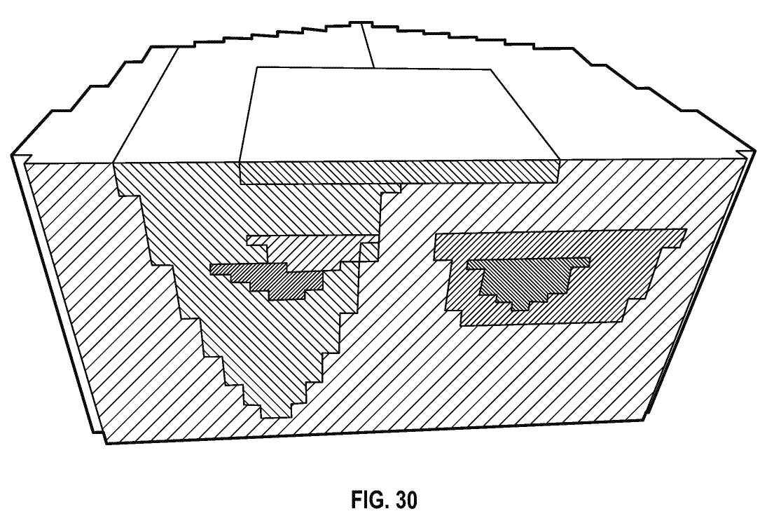

Each geobody is named in the geobody scheme, and may have a host stratum or geobody identified. The host is the geology that had already been deposited when the geobody formed. For some types of geobody, for example a fluvial channel, the host is the geology that was eroded into to form the channel. This erosion may also have cut into deeper, possibly older, strata or geobodies. The geobody scheme therefore effectively limits which cells can be reallocated to each geobody, based on a partial ordering of erosional and depositional processes. FIG. 30 illustrates an example grid showing large geobodies cutting into a background stratum, with some minor geobodies within major ones.

The relationship between geobodies and host strata is also available when reporting volumetrics, with the option of geobody volumes being included in the data for the host strata. The geobody allocation is made after the strata allocation. For the purposes of allocating cells to model structural units, if a cell has been allocated to a geobody, then the geobody identifier is used instead of the stratum identifier when combining with the segment identifier.

### Abstract Dynamic Grid Generation

The discussion below describes the use of an abstract grid for a highly automated workflow for building reservoir simulation models. Numerical reservoir simulation uses gridding to divide the continuous volume of subsurface rock into cells. The properties of the rock are considered to be homogeneous within a cell, for the purposes of subsequent mathematical calculations to determine the volume of fluids in place in the pore spaces of the rock, and how those fluids are expected to move between cells when wells drilled into the rock are opened to flow. As the amount of computation needed to simulate flow is much greater than that needed for static volumetric calculations, it may be possible for a fine cellular model, e.g., a geomodel or static model, to be constructed and used for static volumetric calculations, with a coarser cellular model, possibly with larger cells, being derived from it for flow simulation purposes.

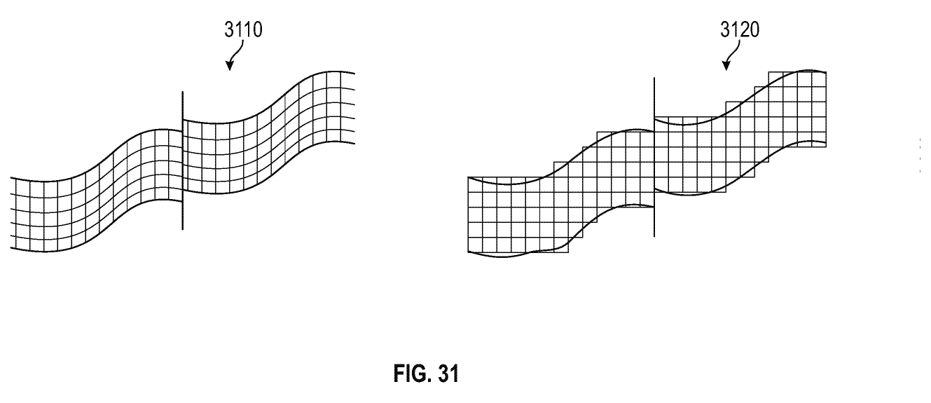

FIG. 31 illustrates example grids of a subsurface area. Grid 3110 is a corner point grid that conforms to surfaces. Grid 3120 is a regular grid that does not conform to geological surfaces with discretized horizons. For both grid 3110 and grid 3120, finer grid cells allow a closer match to the original geometries of the input surfaces. In some implementations, corner point grids are used, where, in ijk space, the k planes follow the geological bedding surfaces as illustrated by grid 3110. In some implementations, the subsurface area may be divided into a regular grid, which may be referred to as a voxel or lattice grid. This brings simplifications in some areas and complexity in others. The discussion below describes how to take a populated static grid and convert it into a representation for flow simulation. In some implementations, the static grid is a regular grid and similar principles apply for taking a corner point grid through this process. The grid 3120 includes blocks with a center point that is between the curved lines. Blocks that have a center point that is outside of the curved lines are not included in the grid 3120.

When passing a grid model to reservoir simulator software, the first operation that the simulator code takes is a pre-processing step to initialize the relevant arrays into computer memory. As properties within each cell are assumed to be homogenous, this step can discard the specific geometries of each cell, retaining just a representative depth (center point) and pore volume derived from the actual cell geometry. Within the computer memory, cells are represented as being points (nodes) in space, with a depth, pressure, pore volume, saturation and some other properties. Alongside these property arrays, the simulator code constructs a list of connections to keep track of the active paths for flow between each cell and its neighbors. In some cases, non-neighbor connections are possible, such as connections between cells that do not share a boundary in the grid geometry. The transmissibility, for example, the strength of connection, for each active connection is calculated and stored in memory. In some implementations, reservoir simulator packages allow the simulator to be fed this data direct – in “unstructured” form, in other words, without the geometric framework of a grid.

An example workflow may utilize this abstract representation of the grid outside of the reservoir simulator package. Having generated a fine scale regular static model, an example workflow allows flexibility in the resolution of the model passed to the simulator for flow simulation. Depending upon the analysis being performed, collections of neighboring cells are grouped in the fine scale model together and represent these as points in space, with relevant properties and connections to feed to the reservoir simulator. Changing the grouping of these cells is an inexpensive computation when compared to the initial generation of the fine scale grid, which is built from input horizons and fault surfaces.

An example workflow allows the use of the same fine scale input model to generate simplified “material balance” models that have minimal numbers of cells, such as one per fault block, through to complex models with much finer resolution. This gives flexibility in dynamic model resolution.

As the abstract grid representation is generated directly, rather than passing to a simulator pre-processor to perform this procedure based on input cell geometries, the transmissibilities should be computed between the nodes, which will be described in more detail below.

Having models at different scales or upscaling finer models to get coarser representations is one example. Other example workflows may require decisions on resolution and grid design to be made in advance, such as intentionally building the finer scale geological grid at a resolution that will ultimately be upscaled at a known ratio, through a "coarse-fine-coarse" grid workflow.

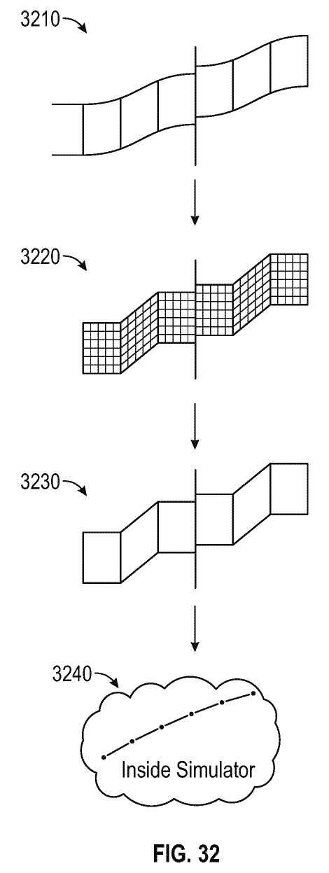

FIG. 32 illustrates an example model building process using a coarse-fine-coarse setup. Stage 3210 illustrates an example corner point model that is built at the desired final scale. Stage 3220 illustrates an example fine scale model that is built from the stage 3210 corner point model and populated. Stage 3230 illustrates the model that is upscaled back to the desired scale. Stage 3240 illustrates the representation of the model that is provided to the simulator, which is a network with nodes that represent each portion of the model and edges to connect the nodes.

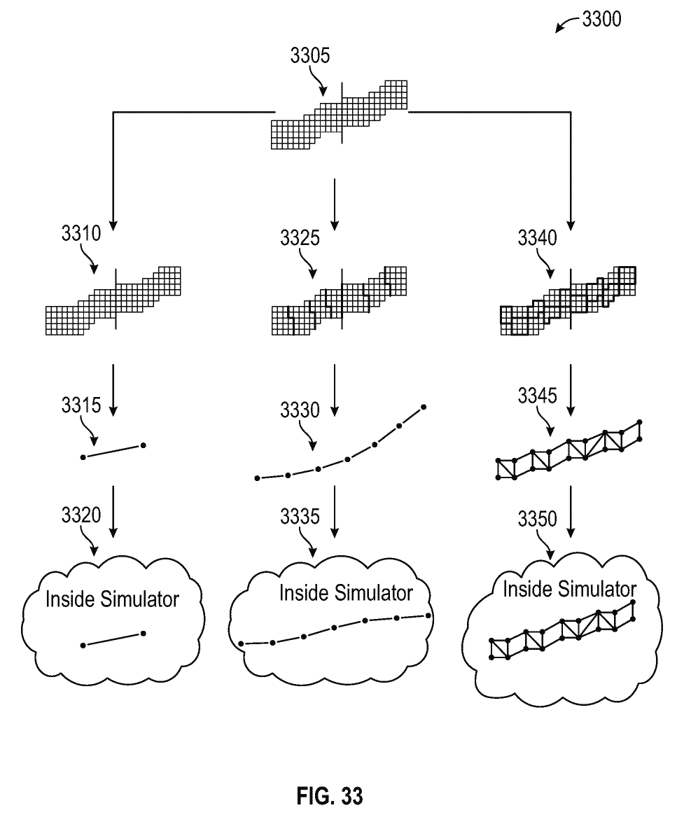

FIG. 33 illustrates an example abstract dynamic model process 3300 that generates abstract models with three different resolutions by allocating cells to different size cell groups. The abstract models can then be provided to the simulator. The fine scale grid 3305 may be the starting point for different processes with different resolutions. The grid 3310 may illustrate an allocation of the cells of the fine scale grid 3305 into two MSUs. One MSU may be on the left of a fault, and another MSU may be on the right of the fault. The network 3315 is a representation of the grid 3310. One of the nodes in the network 3315 corresponds to one of the MSUs of grid 3310, and the other node in the network 3315 corresponds to the other MSU of grid 3310. In stage 3320, the network 3315 is provided to the simulator.

The grid 3325 may illustrate an allocation of the cells of the fine scale grid 3305 into six abstract dynamic cells with bold lines between each. A model structural unit may be broken up into multiple abstract dynamic cells. The network 3330 is a representation of the grid 3325. Each of the nodes in the network 3330 corresponds to a different abstract dynamic cell of the grid 3325. The edges of the nodes represent the transmissibilities between the pairs of abstract dynamic cells that correspond to the node pairs. In stage 3335, the network 3330 is provided to the simulator.

The grid 3340 may illustrate an allocation of the cells of the fine scale grid 3305 into multiple abstract dynamic cells. The network 3345 is a representation of the grid 3340. Each of the nodes in the network 3345 corresponds to a different abstract dynamic cell of the grid 3340. The edges of the nodes represent the transmissibilities between the pairs of abstract dynamic cells that correspond to the node pairs. Many of the nodes in network 3345 are connected to multiple other nodes. Pairs of abstract dynamic cells may have a transmissibility between the two if they share a side (or face in three dimensions) or portion of a side (or face in three dimensions). In some implementations, Pairs of abstract dynamic cells that share a corner in two dimensions, an edge in two dimensions, and/or a corner in three dimensions may have a transmissibility between the two. If pairs of abstract dynamic cells do not have a transmissibility between the two, then the network 3345 does not include an edge to connect the two nodes that represent the pair. In stage 3350, the network 3345 is provided to the simulator.

As is illustrated by the processes 3300, each of the networks 3315, 3330, and 3345 represents the grid 3305, but at different levels of detail. The higher the level of detail, the more computing resources needed, but the accuracy of the simulation result may be better.

In some implementations, a process of “auto subdivision” may be implemented. For scenarios where the desired dynamic grid has more than one cell per intersection of fault block and segment, this process provides an automated method for identifying fine scale cells that should be grouped together and upscaled. Auto subdivision is an iterative process that continues until certain termination criteria are met. These criteria can include, a minimum number of fine scale cells within the resultant abstract cell, a maximum aspect ratio, a maximum length, and/or any other similar criteria.

A series of rules may define how the iteration proceeds. To facilitate specific areas of interest having higher resolution, the processes uses the concept of importance. This can be thought of as having units per unit area. Importance is a grid parameter that is defined on the fine scale static grid. The auto-subdivision process allows terminating criteria to be set to have a target importance per cell group. In some terminology, these cell groups are called abstract dynamic cells. The subdivision process may continue until the sum of the importance values of the fine scale cells within each abstract dynamic cell reaches a specified value.

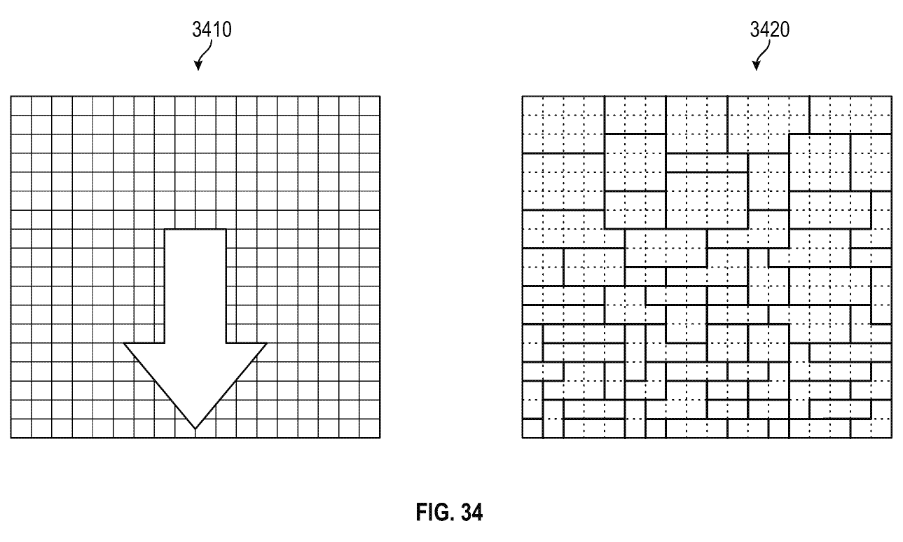

FIG. 34 illustrates an example grid where the cells have varying importance values. In grid 3410, the cells have increasing importance values towards the bottom of the grid. In grid 3420, the importance values may be used to yield an abstract dynamic cell definition, as illustrated by the solid lines, that generally has a finer resolution at the lower end of the field, where the importance values are higher. In other words, the cells with higher importance values may be grouped into smaller abstract dynamic cells. The cells with the highest importance, which are those at the bottom of the grid 3410, are generally grouped into abstract dynamic cells with fewer cells than the abstract dynamic cells at the top of the grid 3410. The cells with the lowest importance, which are those at the top of the grid 3410, are grouped into abstract dynamic cells that include more cells than the abstract dynamic cells at the bottom of the grid 3410. Importance is one of the factors used to group the regular cells into abstract dynamic cells. Because importance is just one of the factors, some of the abstract dynamic cells near the bottom of the grid 3420 may be similar in shape and/or number of cells than the abstract dynamic cells near the top of the grid 3420. There are various use cases for importance such as having higher resolution dynamic cells around areas with well control, and/or having specific areas/segments of interest with high resolution and more distal parts of the field modelled at lower resolution so that they provide material balance boundary condition effects but do not place unnecessary strain on computational time or memory.

### Tensor Permeability Upscaling from Regular to Abstract Grids

The process described below enables the upscaling of rock permeability from fine, regular grids to coarser abstract grids whose cells are formed from uneven aggregations of the fine grid cells. When building models for fluid flow simulation, the models may be gridded on a very fine scale in order to capture geological variation accurately. However, numerical flow simulation on these models may be costly in terms of time and computing resources, making it difficult or unfeasible to use the fine scale grid for simulation directly. As a result, coarser grids which are less demanding of computer resources are used. Upscaling is the process by which properties are calculated for coarse grid cells in a way that best captures the smaller scale effects of the properties on the finer grid. The process described below focusses on the upscaling of rock permeability for single phase fluid flow by performing single-phase pressure solutions.

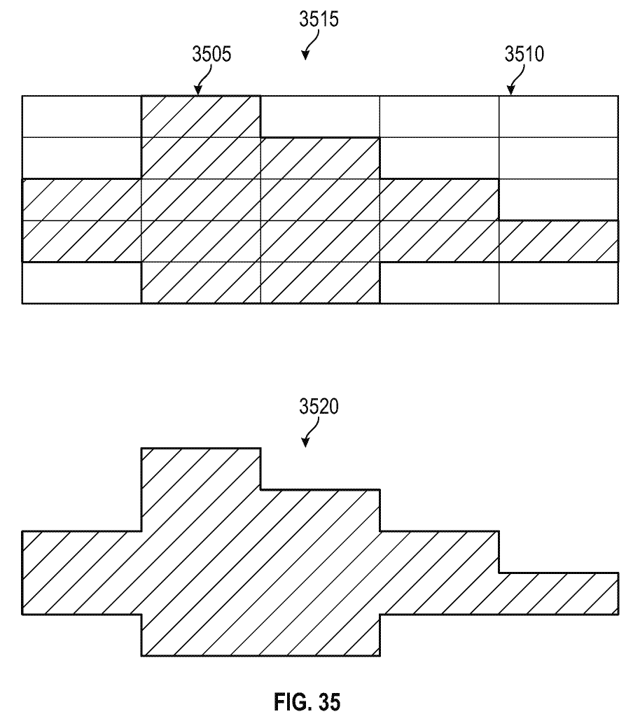

FIG. 35 illustrates an example two-dimensional regular grid with a set of cells comprising a single coarse abstract cell. Grid 3515 includes cells with two different types of shading. Cells in group 3505 are selected to be combined into a single coarse abstract cell, which is cell 3520. Cells in group 3510 are within grid 3515 but outside of the group 3505.

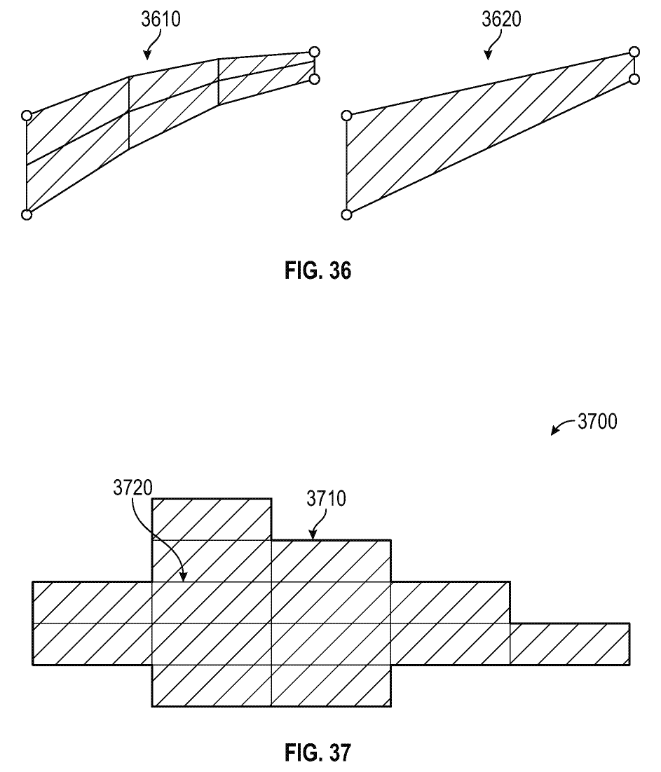

In some implementations, the coarse and fine grids are constructed using “corner point” grid cells where the tops and bottoms of the cells align with the geological strata, and where the corners of the coarse grid cells are congruent with some of the corners of the fine grid cells. FIG. 36 illustrates an example fine grid 3610 and a coarse grid 3620 in an example corner point upscaling problem. The circle point set of grid 3610 and the circle point set of grid 3620 are congruent. The cells of grid 3610 are not regular but are aligned with geological strata.

Maintaining the grid cell alignments with geological strata ensures that the “two point flux approximation” (TPFA) finite difference schemes used in multi-phase flow simulators do not incur large discretization errors, and having congruency between fine and coarse grids simplifies the upscaling process.

The upscaling approach differs from the previously discussed approach in that neither fine nor coarse simulation grids are corner point. In the upscaling approach the fine grid is entirely regular and orthogonal (a voxel grid) and the coarse grid is abstract in general but broadly conforming to geological strata. FIG. 37 illustrates an example of this and illustrates an example two-dimensional coarse abstract cell 3700 built from an aggregation of two dimensional fine scale regular grid cells. The abstract cell volume is inside the bold border 3710. The bold border 3710 denotes the boundary of the abstract cell. The fine scale cell boundaries are thin lines 3720.

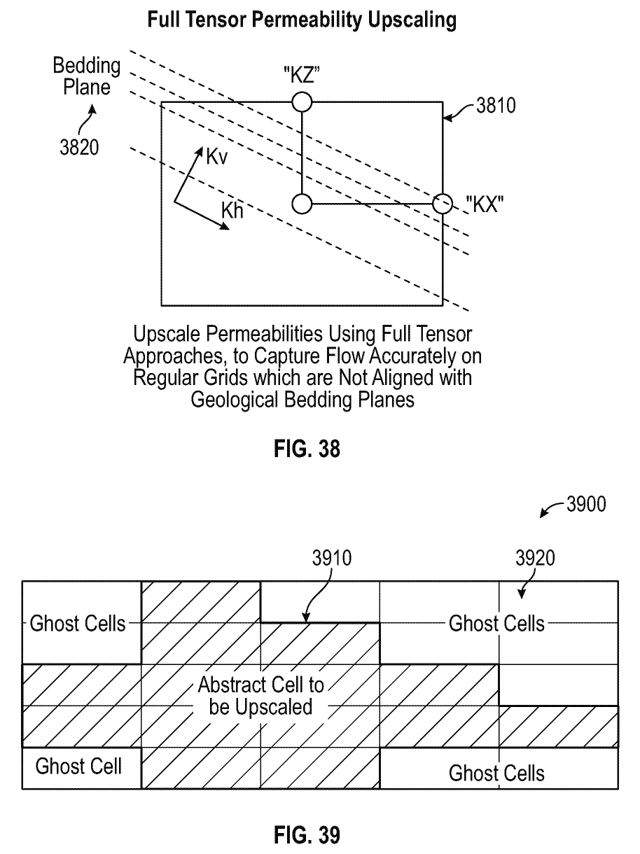

This approach with gridding leads to at least two technical challenges. Firstly, use of a regular, orthogonal, fine grid simplifies many things in the modelling process. However, it adds a challenge for upscaling and flow representation. The fine grid cells are misaligned with the geological strata, a situation in which it is known that two point flux approximation finite difference schemes incur large errors. This challenge is illustrated in FIG. 38 that illustrates an example cell 3810 and bedding plane 3820. The cell 3810 is aligned with a KZ and KX axis. The bedding plane is aligned with a Kv and Kh axis. The two axes are not aligned. This challenge may require full tensor permeability upscaling. Upscaling permeabilities using full tensor approaches helps to capture flow accurately on regular grids that are not aligned with geological bedding planes.

Secondly, the lack of alignment and congruence between fine grid and coarse grid makes the upscaling problem more challenging. In some implementations, the upscaling pressure solution is carried out on a cuboid box of cells, something which is implicit in the corner point grid approach. However, there may be numbers of regular fine grid cells which are inside the cuboid box but which are not directly a part of the upscaling calculation for the coarse abstract cell of interest. These “non-participating” cells may be referred to as “ghost cells.” FIG. 39 illustrates an example cuboid 3900 upscaling computational box in two dimensions for a single coarse abstract cell 3910. The fine grid ghost cells 3920 are outside of the abstract cell 3910 and inside the cuboid 3900.

Ghost cells have their own tensor permeability properties and therefore add complexity to the upscaling algorithm, implying the need for additional computer memory and computational time, despite their not belonging to the volume being upscaled. In some implementations, there are more ghost cells inside the cuboid box than cells belonging to the coarse cell being upscaled. Additional complexity occurs due to the boundary surface of the coarse cell being rugose, as is apparent from the image above. To perform an upscaling calculation, the boundary should to be computationally known so that boundary conditions can be applied to the boundary’s cell faces.

To address a first problem, which is the misalignment of fine grid cells and geological strata, the process uses a finite difference scheme which is better suited to misaligned grids, and which corrects for the errors that occur in this situation with two-point flux approximation schemes. Such finite difference schemes are able to model full tensor permeability which allows them to correct for the aforementioned misalignment.

The upscaling method may include the ability to apply Dirichlet (pressure) boundary conditions in the method since these may be part of the upscaling method. In some implementations, Neumann (flux) boundary conditions may be used. The upscaling method generates tensor permeability properties on the coarse abstract cells.

The second problem may be related to the use of computing resources. The upscaling method may be computing resource intensive. The upscaling method may generate a 7n by 7n matrix with more blocky, non-banded structure leading to higher demands on memory and computation time, where n is the number of fine grid cells.

The upscaling method from regular fine cells to abstract coarse cells results in significant numbers of “non-participating” ghost cells being involved in the upscaling calculation. These ghost cells consume memory and computation time despite being logically outside of, and having little to no influence on the volume of interest being upscaled. To address this challenge, the upscaling method includes a pre-processing step which modifies the structure of the matrix for the blocks corresponding to the ghost cells. This approach is to diagonalize these blocks. This results in the matrix problem becoming easier to solve, thus reducing the needed CPU processing time. The matrix contains fewer non-zero elements, resulting in reduced computer memory requirements. The matrix problem remains identical for the subset of fine grid cells being upscaled.

The method allows for upscaling calculations that generate tensor permeability values for coarse abstract cells from a finer, regular, grid that is not aligned to geological strata in a way that captures off-diagonal flow effects. The method handles “non-participating” ghost cells by modifying their subset of the matrix problem, which makes the upscaling pragmatic and feasible in terms of CPU time expended and memory required. The upscaled tensor permeability values can then be used for computing the coarse cell to coarse cell transmissibility values required by multi-phase flow simulators.

Any of the techniques described above may utilize and/or be performed by any type of computing device. The computing device may be configured to communicate with other computing devices. The computing device may communicate with other computing devices using a wide area network, a local area network, the internet, a wired connection, a wireless connection, and/or any other type of network or connection. The wireless connections may include Wi-Fi, short-range radio, infrared, and/or any other wireless connection. Some of the components of the computing device may be implemented in a single computing device or distributed over multiple computing devices. Some of the components may be in the form of virtual machines or software containers that are hosted in a cloud in communication with disaggregated storage devices. Some of the components may be implemented by one or more processors through the execution of computer-executable instructions stored in memory.

The computing device may include a communication interface, one or more processors, memory, and hardware. The communication interface may include communication components that enable the systems to transmit data and receive data from devices connected to the wireless carrier network. The communication interface may include an interface that is configured to communicate with base stations of a wireless carrier network. The communication interface may receive data that other devices transmit to the base stations and/or transmit data to the base stations for transmission to the other devices. In some implementations, the communication interface may be configured to communicate over a wide area network, a local area network, the internet, a wired connection, a wireless connection, and/or any other type of network or connection. The wireless connections may include Wi-Fi, short-range radio, infrared, and/or any other wireless connection.

The hardware may include user interface, data communication, or data storage hardware. For example, the user interfaces may include a data output device (e.g., visual display, audio speakers), and one or more data input devices. The data input devices may include, but are not limited to, combinations of one or more of keypads, keyboards, mouse devices, touch screens that accept gestures, microphones, voice or speech recognition devices, and any other suitable devices.

The memory may be implemented using computer-readable media, such as computer storage media. Computer-readable media includes, at least, two types of computer-readable media, namely computer storage media and communications media. Computer storage media includes volatile and non-volatile, removable and non-removable media implemented in any method or technology for storage of information such as computer-readable instructions, data structures, program modules, or other data. Computer storage media includes, but is not limited to, RAM, ROM, EEPROM, flash memory or other memory technology, CD-ROM, digital versatile disks (DVD), high-definition multimedia/data storage disks, or other optical storage, magnetic cassettes, magnetic tape, magnetic disk storage or other magnetic storage devices, or any other non-transmission medium that can be used to store information for access by a computing device. In contrast, communication media may embody computer-readable instructions, data structures, program modules, or other data in a modulated data signal, such as a carrier wave, or other transmission mechanism. In some implementations, the data stored in the memory may be stored externally from the systems.

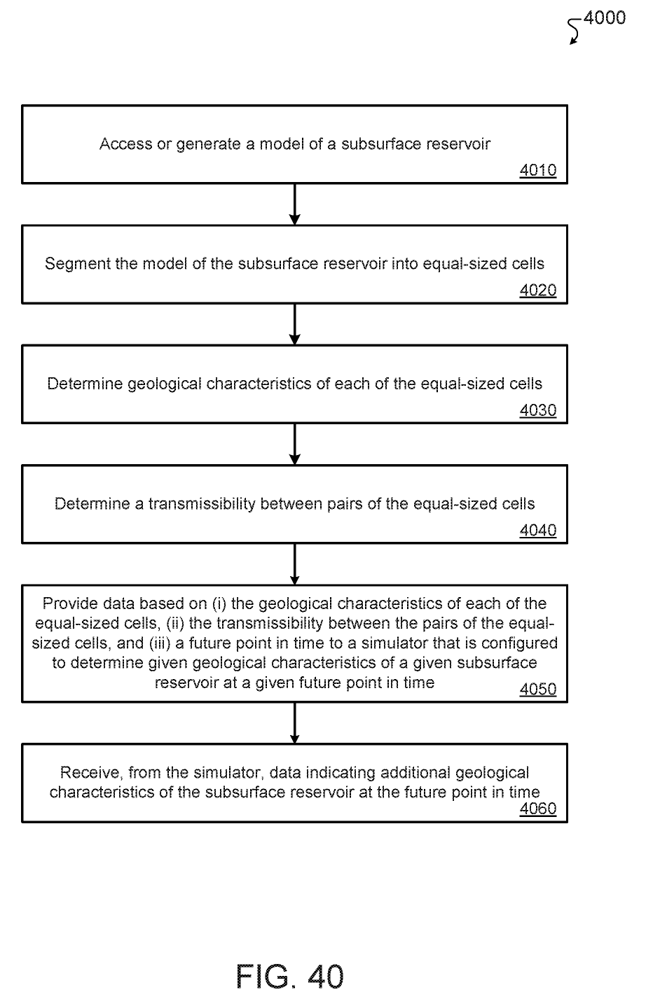

FIG. 40 is a flowchart of an example process 4000 for modeling a reservoir using regular and abstract grids. The process 4000 accesses a model of a subsurface reservoir and splits the model into equal-sized cells. The process 4000 determines geological characteristics and transmissibilities for the equal-sized cells. The process 4000 provides data based on the geological characteristics and transmissibilities to a simulator. The simulator outputs new, estimated geological characteristics, for example flow characteristics, for a time in the future. The process 4000 will be described as being performed by a computing device. The process 4000 may be performed by a single computing device, which may be a virtual device and/or split across multiple computing devices that may include virtual devices. In some implementations, the process 4000 may be performed by an application.

The computing device accesses a model of a subsurface reservoir (4010). In some implementations, the computing device may generate the model of the subsurface reservoir instead of access the model. The subsurface reservoir may have various fluids in it. Some of the fluids may include water and/or fossil fuels. The model may be in three dimensions and may indicate the location of one or more faults and the locations of one or more geological layers, or horizons within the subsurface reservoir.

The computing device segments the model of the subsurface reservoir into equal-sized cells (4020). In some implementations, the cells are regular cells because they are regular polyhedrons. In some implementations, the equal-sized cells are hexahedrons. In some implementations, the equal-sized cells are rectangular prisms. In some implementations, the faces of the equal-sized cells may be parallel or perpendicular with each other. In some implementations, the faces of the equal-sized cells do not align with any of the geological features of the subsurface reservoir, such as faults, horizons, layers, and/or any other similar geological feature. In other words, the geological features may not be perpendicular with one or more of the faces of the equal-sized cells.

The computing device determines geological characteristics of each of the equal-sized cells (4030). In some implementations, the geological characteristics include a pore volume, a depth, a pressure, a saturation, flow, and/or any other similar geological characteristic.

The computing device determines a transmissibility between pairs of the equal-sized cells (4040). The transmissibility may indicate the ability of fluid and pressure changes to move from one cell to another cell. The pairs of the equal-sized cells may be equal-sized cells that share a face. In some implementations, the transmissibility may include a direction.

The computing device provides data based on (i) the geological characteristics of each of the equal-sized cells, (ii) the transmissibility between the pairs of the equal-sized cells, and (iii) a future point in time to a simulator that is configured to determine given geological characteristics of a given subsurface reservoir at a given future point in time (4050). In some implementations, the computing device generates cell groups that each comprise a group of neighboring equal-sized cells of the equal-sized cells. The cell groups may be model structural units or may be abstract dynamic cells. Each cell group may be the same or different sizes. The computing device may provide the geological characteristics of each cell group, the transmissibility between pairs of cell groups, and the future point in time to the simulator.

In some implementations, the computing device generates additional cell groups that are a different size and/or shape than the previous cell groups. The additional cell groups may be larger or smaller than the previous cell groups. The additional cell groups may also each comprise a group of neighboring equal-sized cells of the equal-sized cells. The additional cell groups may have geological characteristics and transmissibilities that are different or the same as the geological characteristics and transmissibilities of the previous cell groups. Because the computing device is able to change the size and/or shape of the cells groups, the cell groups are called abstract dynamic cells.

In some implementations, the computing device generates a network of nodes and edges. Each node corresponds to a cell group and includes the geological characteristics of that cell group. Each edge connects a pair of nodes and includes the transmissibilities from one cell group to another cell group and in the reverse direction. Some node pairs may not be connected by edges.

The computing device receives, from the simulator, data indicating additional geological characteristics of the subsurface reservoir at the future point in time (4060). The simulator may determine the likely movement of fluid within the subsurface reservoir at the future point in time. The additional geological characteristics may indicate the likely movement of fluid. The computing device may receive outputs from the simulator based on the initial cell groups and the second cell groups differently sized cell groups. The computing device may compare the two outputs. If the two output are within a threshold percentage of each other, such as five percent, then the computing device may select the cell groups that are larger because of the reduced computing resources required for simulation and other processing. A user may continue to increase the size of the cell groups until the outputs from the simulator are outside of threshold percentage or range from an original output, such as from cell groups with only one cell. The user may select the cell group size that is the largest, but still has outputs within the threshold percentage or range from an original output.

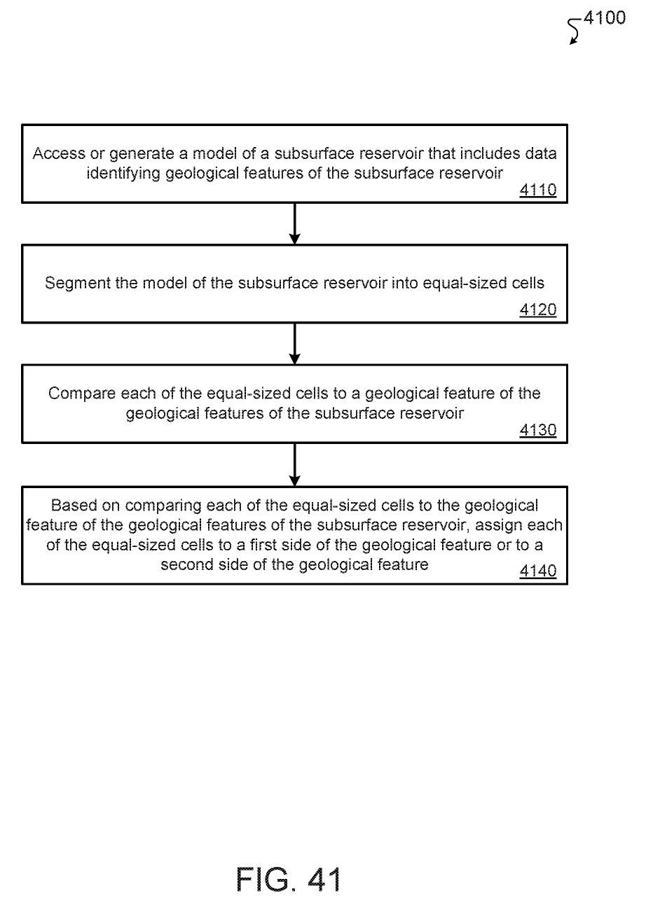

FIG. 41 is a flowchart of an example process 4100 for using a regular grid to model a reservoir. The process 4100 accesses a model of a subsurface reservoir. The process 4100 segments the model into equal-sized cells. Based on a comparison of the equal-sized cells to a geological feature, the process 4100 assigns the equal-sized cells to be located on one side of the geological feature or the other. The process 4100 will be described as being performed by a computing device. The process 4100 may be performed by a single computing device, which may be a virtual device and/or split across multiple computing devices that may include virtual devices. In some implementations, the process 4100 may be performed by an application.

The computing device generates or accesses a model of a subsurface reservoir that includes data identifying geological features of the subsurface reservoir (4110). The geological features may include faults and horizons. There may be multiple faults and/or horizons in the subsurface reservoir. The model may not identify the exact locations or all of the actual faults or horizons and may identify faults or horizons that do not exist.

The computing device segments the model of the subsurface reservoir into equal-sized cells (4120). In some implementations, the computing device generates a cellular grid of regular, equally-sized cells. The cellular grid represents the subsurface reservoir. In some implementations, the equal-sized cells are hexahedrons. In some implementations, the equal-sized cells are rectangular prisms. In some implementations, the faces of the equal-sized cells may be parallel or perpendicular with each other. In some implementations, the faces of the equal-sized cells do not align with any of the geological features of the subsurface reservoir, such as faults, horizons, layers, and/or any other similar geological feature. In other words, the geological features may not be perpendicular with one or more of the faces of the equal-sized cells.

The computing device compares each of the equal-sized cells to a geological feature of the geological features of the subsurface reservoir (4130). Based on comparing each of the equal-sized cells to the geological feature of the geological features of the subsurface reservoir, the computing device assigns each of the equal-sized cells to a first side of the geological feature or to a second side of the geological feature (4140).

In some implementations, the computing device identifies a portion of the cells that intersect a geological feature. In this case, the computing device assigns a face of each equal-sized cell of the portion of the equal-sized cells to the geological feature. In some implementations, the computing device segments the geological feature into triangles. In this case, the computing device compares the faces of the equal-sized cells to the triangles and uses that comparison to assign faces to a geological feature.

In some cases, the computing device may assign ranks to the different geological features as represented by the equal-sized cells of the model of the subsurface reservoir. Some geological features may be major features, such as a major fault. Other geological features may be minor features, such as a minor, smaller fault. The computing device may assign a lower rank to major and/or larger geological features. The computing device may store data indicating this rank with the cells. The computing device may assign a portion of the equal-sized cells that are between the geological feature and the first additional geological feature to a first rank. The computing device may assign a first subportion of the portion of the equal-sized cells that are between the geological feature and the second additional geological feature to a second rank. The computing device may assign a second subportion of the portion of the equal-sized cells that are between the first geological feature and the second additional geological feature to the second rank. With the rank system, a user can select a lower rank to view or process data with higher ranked geological features ignored or bypassed.

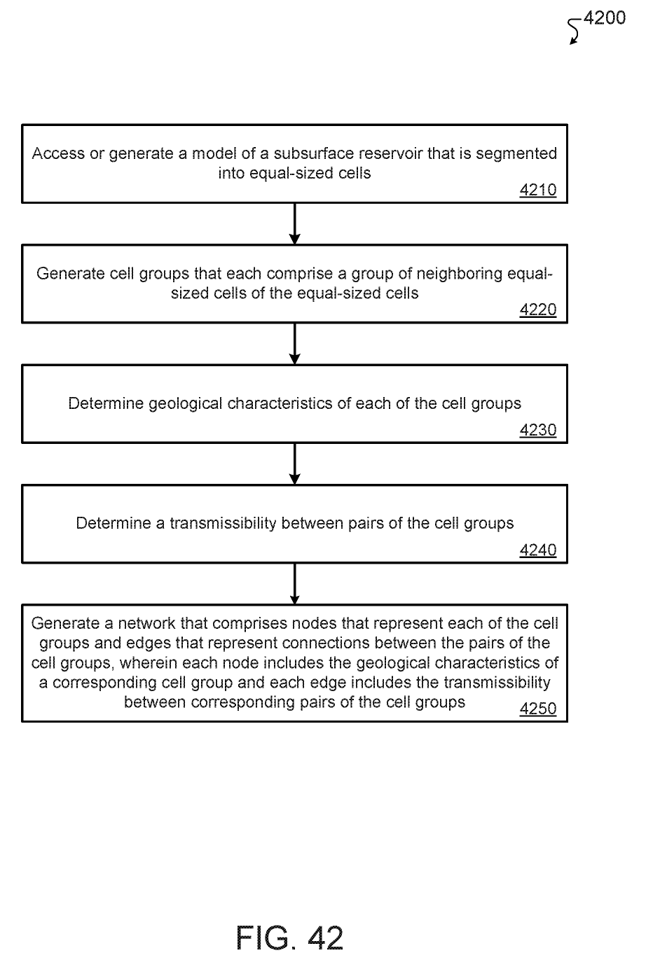

FIG. 42 is a flowchart of an example process 4200 for generating an abstract dynamic grid. The process 4200 accesses a model of a subsurface reservoir that is divided into equal-sized cells. The process 4200 groups the equal-sized cells into larger cell groups that each comprise a group of neighboring cells. The process 4200 determines the geological characteristics for each cell group and transmissibilities for neighboring cell groups. The process 4200 generates a network based on the cell groups. The process 4200 will be described as being performed by a computing device. The process 4200 may be performed by a single computing device, which may be a virtual device and/or split across multiple computing devices that may include virtual devices. In some implementations, the process 4200 may be performed by an application.

The computing device accesses or generates a model of a subsurface reservoir that is segmented into equal-sized cells (4210). In some implementations, the equal-sized cells are hexahedrons. In some implementations, the equal-sized cells are rectangular prisms. In some implementations, the faces of the equal-sized cells may be parallel or perpendicular with each other. In some implementations, the faces of the equal-sized cells do not align with any of the geological features of the subsurface reservoir, such as faults, horizons, layers, and/or any other similar geological feature. In other words, the geological features may not be perpendicular with one or more of the faces of the equal-sized cells.

The model may include geological features of the subsurface reservoir. The geological features may include faults and horizons. There may be multiple faults and/or horizons in the subsurface reservoir. The model may not identify the exact locations or all of the actual faults or horizons and may identify faults or horizons that do not exist.

The computing device generates cell groups that each comprise a group of neighboring equal-sized cells of the equal-sized cells (4220). The cell groups may be abstract dynamic cells. In some implementations, the cell groups that each comprise the group of the neighboring equal-sized cells of the equal-sized cells is based on a minimum number of the neighboring equal-sized cells, a maximum or minimum number of equal-sized cells in a group, a maximum aspect ratio of the cell groups, and a maximum length, width, and/or height of the cell groups. The neighboring equal-sized cells may relate to the number of equal-sized cells that border each of the cell groups. The aspect ratio of the cell groups may relate to a bounding box that encompasses the cell groups and the ratio of the length of the sides of the sides of the bounding box. The bounding box may be a rectangular prism. The length, width, and/or height of the cell groups may relate to the length, width, and/or height of the bounding box.

In some implementations, the equal-sized cells may have an importance value. The importance value may be predetermined. The importance value may be calculated based on geological characteristics of the equal-sized cells. For example, the importance value may be based on a pore volume, a depth, a pressure, a saturation, and/or any other similar characteristic of the cells. The importance value may be based on a permeability of the cell and/or the transmissibility between the cell and a neighboring cell. In some implementations, any of the pore volume, depth, pressure, saturation, permeability, transmissibility, and/or any other similar characteristics is weighted more heavily in the importance value calculation than other characteristics. The goal of the importance value may be to obtain more accurate predictions for certain portions of the underground reservoir.

With an importance value assigned to each of the cells, the computing device may generate cell groups that have a maximum importance value total. This may result in some cell groups including more cells than other cell groups. In some implementations, the computing device may try to generate cell groups with equal importance value totals or have importance value total within a predetermined range.

The computing device determines geological characteristics of each of the cell groups (4230). The geological characteristics comprise a pore volume, a depth, a pressure, a saturation, and/or any other similar characteristics. In some implementations, the computing device determines an arithmetic mean, geometric mean, median, or mode of each of the characteristics for each cell in the group and assigns that value to the cell group. In some implementations, the computing device may generate cell groups that have a target geological characteristic value.

The computing device determines a transmissibility between pairs of the cell groups (4240). The transmissibility may be based on the permeability of each cell group in a pair of cell groups. The transmissibility may be determined for pairs of cell groups that share a face or border. In some implementations, pairs of cell groups share a border or face which may not have a transmissibility because of the inability of liquid to flow between the two cell groups.

The computing device generates a network that comprises nodes that represent each of the cell groups and edges that represent connections between the pairs of the cell groups, wherein each node includes the geological characteristics of a corresponding cell group and each edge includes the transmissibility between corresponding pairs of the cell groups (4250). The computing device may perform the process 4200 again and generate cell groups that are a different size. These new cell groups may be based on different parameters, such as a different importance level total or range, different aspect ratio, different width, length, or height, different number of cells, different number of neighboring cells, and/or any other similar parameter.

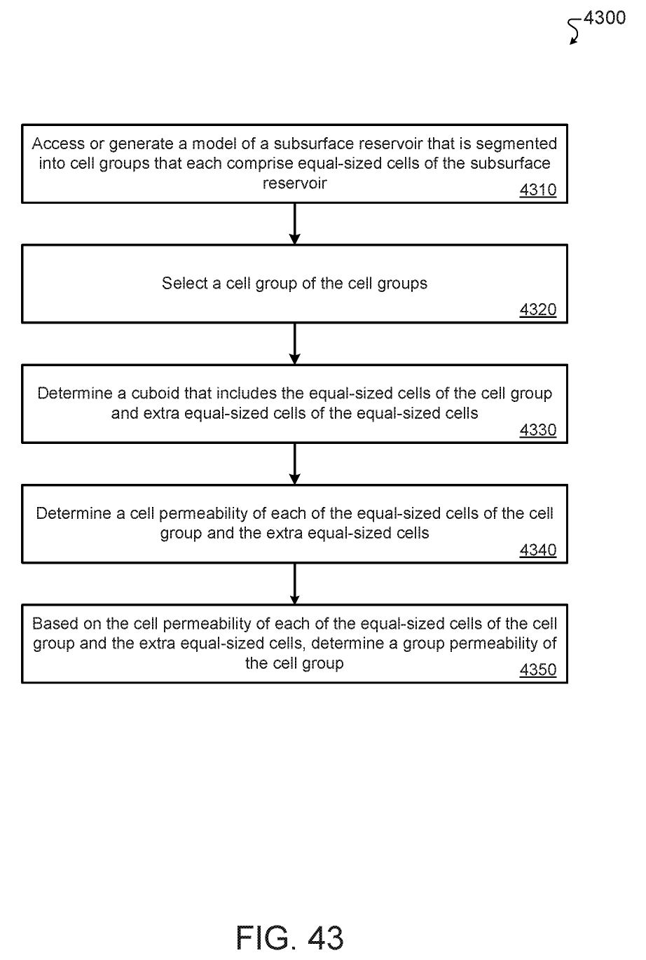

FIG. 43 is a flowchart of an example process 4300 for upscaling tensor permeability from regular to abstract grids. The process 4300 access a model of subsurface reservoir that is divided into cell groups. The process 4300 determines a cuboid that outlines each of the cell groups and additional cells. Based on the cell permeability of each of the cell in a cell group and the additional cells, the process 4300 determines a permeability for the cell group. The process 4300 will be described as being performed by a computing device. The process 4300 may be performed by a single computing device, which may be a virtual device and/or split across multiple computing devices that may include virtual devices. In some implementations, the process 4300 may be performed by an application.

The computing device accesses a model of a subsurface reservoir that is segmented into cell groups that each comprise equal-sized cells of the subsurface reservoir (4310). In some implementations, the equal-sized cells are hexahedrons. In some implementations, the equal-sized cells are rectangular prisms. In some implementations, the faces of the equal-sized cells may be parallel or perpendicular with each other. In some implementations, the faces of the equal-sized cells do not align with any of the geological features of the subsurface reservoir, such as faults, horizons, layers, and/or any other similar geological feature. In other words, the geological features may not be perpendicular with one or more of the faces of the equal-sized cells. The cell groups may be the same size or may vary in size. The cell groups may be rugose. The cell groups may be generated using one or more of the techniques described in process 4200.

The computing device selects a cell group of the cell groups (4320). The computing device may select a cell group based on the location of the cell group within the model, such as selecting a cell group closest to the surface or the bottom of the subsurface reservoir. The computing device may loop through all the cell groups and perform the following actions on each cell group.

The computing device determines a cuboid that includes the equal-sized cells of the cell group and extra equal-sized cells of the equal-sized cells (4330). In some implementations, the cuboid is a rectangular prism. The faces of the cuboid may include some of the faces of the cells in the cell group. In some implementations, the number of extra cells is greater than the number of cells in the cell group. The extra cells may be referred to as ghost cells.

The computing device determines a cell permeability of each of the equal-sized cells of the cell group and the extra equal-sized cells (4340). In some implementations, the cell permeability may be related to the direction and strength that fluid flows between neighboring cells. In some implementations, the direction of fluid flow may not be parallel to any face of the cells, cell groups, and/or cuboid.

Based on the cell permeability of each of the equal-sized cells of the cell group and the extra equal-sized cells, the computing device determines a group permeability of the cell group (4350). In some implementations, the computing device determines a transmissibility between two cell groups based on the permeability of each cell group. In some implementations, the computing device generates a matrix based on the cell permeability of each of the equal-sized cells of the cell group and the extra equal-sized cells. The computing device generates a modified matrix by reducing a number of non-zero elements in the matrix. The computing device determines the permeability using the modified matrix. The modified matrix maintains data related to the equal-sized cells of the cell group included in the matrix. In some implementations, data related to the ghost cells is lost when generating the modified matrix.

While several implementations have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted or not implemented. Accordingly, the scope of protection is not limited to the embodiments described herein, but is only limited by the claims that follow, the scope of which shall include all equivalents of the subject matter of the claims. Unless expressly stated otherwise, the steps in a method claim may be performed in any order. The recitation of identifiers such as (a), (b), (c) or (1), (2), (3) before steps in a method claim are not intended to and do not specify a particular order to the steps, but rather are used to simplify subsequent reference to such steps.

Also, techniques, systems, subsystems, and methods described and illustrated in the various implementations as discrete or separate may be combined or integrated with other systems, modules, techniques, or methods without departing from the scope of the present disclosure. Other items shown or discussed as directly coupled or communicating with each other may be indirectly coupled or communicating through some interface, device, or intermediate component, whether electrically, mechanically, or otherwise. Other examples of changes, substitutions, and alterations are ascertainable by one skilled in the art and could be made without departing from the spirit and scope disclosed herein.

Each and every claim is incorporated into the specification as an aspect of the present disclosure. Thus, the claims are a further description and are an addition to the aspects of embodiments disclosed herein. The discussion of a reference herein is not an admission that it is prior art to the presently disclosed subject matter, especially any reference that may have a publication date after the priority date of this application. The disclosures of all patents, patent applications, and publications cited herein are hereby incorporated by reference, to the extent that they provide exemplary, procedural or other details supplementary to those set forth herein.

What is claimed is:

1. A computer-implemented method, comprising:
accessing or generating a model of a subsurface reservoir;
segmenting the model of the subsurface reservoir into equal-sized cells;
determining geological characteristics of each of the equal-sized cells;
determining a transmissibility between pairs of the equal-sized cells;
providing data based on: (i) the geological characteristics of each of the equal-sized cells, (ii) the transmissibility between the pairs of the equal-sized cells, and (iii) a future point in time to a simulator that is configured to determine given geological characteristics of a given subsurface reservoir at a given future point in time; and
receiving, from the simulator, data indicating additional geological characteristics of the subsurface reservoir at the future point in time.

2. The method of claim 1, wherein the model of the subsurface reservoir comprises data indicating fault locations of one or more faults and layer locations of one or more geological layers within the subsurface reservoir.

3. The method of claim 1, comprising:
generating cell groups that each comprise a group of neighboring equal-sized cells of the equal-sized cells,
wherein providing the data based on (i) the geological characteristics of each of the equal-sized cells, (ii) the transmissibility between the pairs of the equal-sized cells, and (iii) a future point in time to the simulator comprises providing data identifying the cell groups to the simulator.

4. The method of claim 3, comprising:
generating additional cell groups that each comprise a different group of neighboring equal-sized cells of the equal-sized cells;
providing data identifying the additional cell groups and the data based on (i) the geological characteristics of each of the equal-sized cells, (ii) the transmissibility between the pairs of the equal-sized cells, and (iii) the future point in time to the simulator;
receiving, from the simulator, additional data indicating other geological characteristics of the subsurface reservoir at the future point in time;
comparing the additional geological characteristics of the subsurface reservoir to the other geological characteristics of the subsurface reservoir; and
based on comparing the additional geological characteristics of the subsurface reservoir to the other geological characteristics of the subsurface reservoir, selecting the cell groups or the additional cell groups for subsequent inputs to the simulator.

5. The method of claim 3, comprising:
generating a network that comprises nodes that represent each of the cell groups and edges that represent connections between pairs of the cell groups, wherein each node includes cell group geological characteristics of a corresponding cell group and each edge includes a cell group pair transmissibility between corresponding pairs of the cell groups,
wherein providing the data identifying the cell groups and the data based on (i) the geological characteristics of each of the equal-sized cells, (ii) the transmissibility between the pairs of the equal-sized cells, and (iii) a future point in time to the simulator comprises providing the network to the simulator.

6. The method of claim 1, wherein the geological characteristics comprise a pore volume, a depth, a pressure, a saturation, and a flow.

7. The method of claim 1, wherein the equal-sized cells are hexahedrons.

8. A system, comprising:
one or more processors; and
memory including a plurality of computer-executable components that are executable by the one or more processors to perform acts comprising:
accessing or generating a model of a subsurface reservoir;
segmenting the model of the subsurface reservoir into equal-sized cells;
determining geological characteristics of each of the equal-sized cells;
determining a transmissibility between pairs of the equal-sized cells;
providing data based on: (i) the geological characteristics of each of the equal-sized cells, (ii) the transmissibility between the pairs of the equal-sized cells, and (iii) a future point in time to a simulator that is configured to determine given geological characteristics of a given subsurface reservoir at a given future point in time; and
receiving, from the simulator, data indicating additional geological characteristics of the subsurface reservoir at the future point in time.

9. The system of claim 8, wherein the model of the subsurface reservoir comprises data indicating fault locations of one or more faults and layer locations of one or more geological layers within the subsurface reservoir.

10. The system of claim 8, wherein the acts further comprise:
generating cell groups that each comprise a group of neighboring equal-sized cells of the equal-sized cells,
wherein providing the data based on (i) the geological characteristics of each of the equal-sized cells, (ii) the transmissibility between the pairs of the equal-sized cells, and (iii) a future point in time to the simulator comprises providing data identifying the cell groups to the simulator.

11. The system of claim 10, wherein the acts further comprise:
generating additional cell groups that each comprise a different group of neighboring equal-sized cells of the equal-sized cells;
providing data identifying the additional cell groups and the data based on (i) the geological characteristics of each of the equal-sized cells, (ii) the transmissibility between the pairs of the equal-sized cells, and (iii) the future point in time to the simulator;
receiving, from the simulator, additional data indicating other geological characteristics of the subsurface reservoir at the future point in time;
comparing the additional geological characteristics of the subsurface reservoir to the other geological characteristics of the subsurface reservoir; and
based on comparing the additional geological characteristics of the subsurface reservoir to the other geological characteristics of the subsurface reservoir, selecting the cell groups or the additional cell groups for subsequent inputs to the simulator.

12. The system of claim 10, wherein the acts further comprise:
generating a network that comprises nodes that represent each of the cell groups and edges that represent connections between pairs of the cell groups, wherein each node includes cell group geological characteristics of a corresponding cell group and each edge includes a cell group pair transmissibility between corresponding pairs of the cell groups,
wherein providing the data identifying the cell groups and the data based on (i) the geological characteristics of each of the equal-sized cells, (ii) the transmissibility between the pairs of the equal-sized cells, and (iii) a future point in time to the simulator comprises providing the network to the simulator.

13. The system of claim 8, wherein the geological characteristics comprise a pore volume, a depth, a pressure, a saturation, and a flow.

14. The system of claim 8, wherein the equal-sized cells are hexahedrons.

15. One or more non-transitory computer-readable media storing computer-executable instructions that upon execution cause one or more processors to perform acts comprising:
accessing or generating a model of a subsurface reservoir;
segmenting the model of the subsurface reservoir into equal-sized cells;
determining geological characteristics of each of the equal-sized cells;
determining a transmissibility between pairs of the equal-sized cells;
providing data based on: (i) the geological characteristics of each of the equal-sized cells, (ii) the transmissibility between the pairs of the equal-sized cells, and (iii) a future point in time to a simulator that is configured to determine given geological characteristics of a given subsurface reservoir at a given future point in time; and
receiving, from the simulator, data indicating additional geological characteristics of the subsurface reservoir at the future point in time.

16. The media of claim 15, wherein the model of the subsurface reservoir comprises data indicating fault locations of one or more faults and layer locations of one or more geological layers within the subsurface reservoir.

17. The media of claim 15, wherein the acts further comprise:
generating cell groups that each comprise a group of neighboring equal-sized cells of the equal-sized cells,
wherein providing the data based on (i) the geological characteristics of each of the equal-sized cells, (ii) the transmissibility between the pairs of the equal-sized cells, and (iii) a future point in time to the simulator comprises providing data identifying the cell groups to the simulator.

18. The media of claim 17, wherein the acts further comprise:
generating additional cell groups that each comprise a different group of neighboring equal-sized cells of the equal-sized cells;
providing data identifying the additional cell groups and the data based on (i) the geological characteristics of each of the equal-sized cells, (ii) the transmissibility between the pairs of the equal-sized cells, and (iii) the future point in time to the simulator;
receiving, from the simulator, additional data indicating other geological characteristics of the subsurface reservoir at the future point in time;
comparing the additional geological characteristics of the subsurface reservoir to the other geological characteristics of the subsurface reservoir; and
based on comparing the additional geological characteristics of the subsurface reservoir to the other geological characteristics of the subsurface reservoir, selecting the cell groups or the additional cell groups for subsequent inputs to the simulator.

19. The media of claim 17, wherein the acts further comprise:
generating a network that comprises nodes that represent each of the cell groups and edges that represent connections between pairs of the cell groups, wherein each node includes cell group geological characteristics of a corresponding cell group and each edge includes a cell group pair transmissibility between corresponding pairs of the cell groups,
wherein providing the data identifying the cell groups and the data based on (i) the geological characteristics of each of the equal-sized cells, (ii) the transmissibility between the pairs of the equal-sized cells, and (iii) a future point in time to the simulator comprises providing the network to the simulator.

20. The media of claim 15, wherein the geological characteristics comprise a pore volume, a depth, a pressure, a saturation, and a flow.
